(19) United States
(12) Patent Application Publication
(10) Pub. No.: US 2017/0256544 A1
(43) Pub. Date: Sep. 7, 2017

(54) SEMICONDUCTOR DEVICE INCLUDING MOS TRANSISTOR

(71) Applicant: SAMSUNG ELECTRONICS CO., LTD., Suwon-si (KR)

(72) Inventors: Young Suk CHAI, Seoul (KR); Hu Yong LEE, Seoul (KR); Sang Yong KIM, Suwon-si (KR); Taek Soo JEON, Yongin-si (KR); Won Keun CHUNG, Seoul (KR); Sang Jin HYUN, Suwon-si (KR)

(21) Appl. No.: 15/351,673

(22) Filed: Nov. 15, 2016

(30) Foreign Application Priority Data
Mar. 2, 2016 (KR) 10-2016-0025148

(51) Int. Cl. H01L 27/092; H01L 29/423; H01L 21/306; H01L 21/311; H01L 29/51; H01L 21/8234

(52) U.S. Cl. CPC H01L 27/0922; H01L 29/517; H01L 29/513; H01L 21/823412; H01L 21/30604; H01L 21/31111; H01L 21/31144; H01L 29/42392; H01L 21/823437

(57) ABSTRACT

A semiconductor device including a MOS transistor is provided. The semiconductor device may include a first MOS transistor including first source/drain regions, a first semiconductor layer between the first source/drain regions, a first gate electrode structure, and a first gate dielectric structure; and a second MOS transistor including second source/drain regions, a second semiconductor layer between the second source/drain regions, a second gate electrode structure, and a second gate dielectric structure. The first gate dielectric structure and the second gate dielectric structure include a first common dielectric structure; the first gate dielectric structure includes a first upper dielectric on the first common dielectric structure; the second gate dielectric structure includes the first upper dielectric and a second upper dielectric; and one of the first upper dielectric and the second upper dielectric is a material forming a dipole layer.

### CROSS-REFERENCE TO RELATED APPLICATION

Korean Patent Application No. 10-2016-0025148, filed on Mar. 2, 2016, in the Korean Intellectual Property Office, and entitled: “Semiconductor Device Including MOS Transistor,” is incorporated by reference herein in its entirety.

### BACKGROUND

1. Field

Example embodiments relate to a semiconductor device including a metal oxide semiconductor (MOS) transistor and a method of forming the same.

2. Description of the Related Art

As the tendency has been for semiconductor devices to be highly integrated, the size of MOS transistors has gradually been reduced. As MOS transistors are disposed within limited space which has gradually been reduced, provisions to reduce process defects become important.

### SUMMARY

Embodiments are directed to a semiconductor device, including a first MOS transistor including first source/drain regions disposed on a semiconductor substrate, a first semiconductor layer disposed between the first source/drain regions, a first gate electrode structure intersecting the first semiconductor layer and surrounding the first semiconductor layer, and a first gate dielectric structure disposed between the first semiconductor layer and the first gate electrode structure, and a second MOS transistor including second source/drain regions disposed on the semiconductor substrate, a second semiconductor layer disposed between the second source/drain regions, a second gate electrode structure intersecting the second semiconductor layer and surrounding the second semiconductor layer, and a second gate dielectric structure disposed between the second semiconductor layer and the second gate electrode structure. The first gate dielectric structure and the second gate dielectric structure may include a first common dielectric structure. In addition, the first gate dielectric structure may include a first upper dielectric disposed on the first common dielectric structure, while the second gate dielectric structure may include the first upper dielectric and a second upper dielectric. Furthermore, one of the first upper dielectric and the second upper dielectric may be provided as a material forming a dipole layer. According to an aspect of the present inventive concept, the first upper dielectric of the first gate dielectric may be disposed between the first common dielectric structure of the first gate dielectric and the first gate electrode structure. In addition, the first upper dielectric and the second upper dielectric of the second gate dielectric structure may be disposed between the first common dielectric structure of the second gate dielectric structure and the second gate electrode structure.

Embodiments are also directed to a semiconductor device, including a first MOS transistor disposed on the semiconductor substrate and including a first gate including a first gate dielectric structure and a first gate electrode structure, a second MOS transistor disposed on the semiconductor substrate and including a second gate including a second gate dielectric structure and a second gate electrode structure, a third MOS transistor disposed on the semiconductor substrate and including a third gate including a third gate dielectric structure and a third gate electrode structure, and a fourth MOS transistor disposed on the semiconductor substrate and including a fourth gate including a fourth gate dielectric structure and a fourth gate electrode structure. Each of the first to fourth gate dielectric structures may include a common dielectric structure. In addition, the first gate dielectric structure may include a first upper dielectric on the common dielectric structure, while the fourth gate dielectric structure may include a second upper dielectric on the common dielectric structure. Furthermore, the second gate dielectric structure and the third gate dielectric structure may include a mixture of the first upper dielectric and the second upper dielectric.

### BRIEF DESCRIPTION OF DRAWINGS

Features will become apparent to those of skill in the art by describing in detail exemplary embodiments with reference to the attached drawings in which:

FIG. 1 illustrates a plan view of a semiconductor device according to an example embodiment;

FIGS. 2 to 5 illustrate cross-sectional views of a semiconductor device according to an example embodiment;

FIG. 6 illustrates a plan view of a semiconductor device according to an example embodiment;

FIGS. 7 to 10 illustrate cross-sectional views of a semiconductor device according to an example embodiment;

FIG. 11 illustrates a plan view of a semiconductor device according to an example embodiment;

FIGS. 12A to 12B illustrate cross-sectional views of a semiconductor device according to an example embodiment;

FIG. 13 illustrates a partially enlarged view of a portion of a semiconductor device according to an example embodiment;

FIG. 14 illustrates a plan view of a semiconductor device according to an example embodiment;

FIGS. 15A and 15B illustrate partially enlarged views of a portion of a semiconductor device according to an example embodiment;

FIG. 16A illustrates a plan view of a semiconductor device according to an example embodiment;

FIG. 16B illustrates a partially enlarged view of a portion of a semiconductor device according to an example embodiment;

FIG. 17A illustrates a plan view of a semiconductor device according to an example embodiment;

FIG. 17B illustrates a partially enlarged view of a portion of a semiconductor device according to an example embodiment; and

FIGS. 18 to 37B illustrate views illustrating a method of forming a semiconductor device according to example embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art. In the drawing figures, the dimensions of layers and regions may be exaggerated for clarity of illustration. Like reference numerals refer to like elements throughout.

<<Semiconductor Device with a Plurality of PMOS Transistors>>

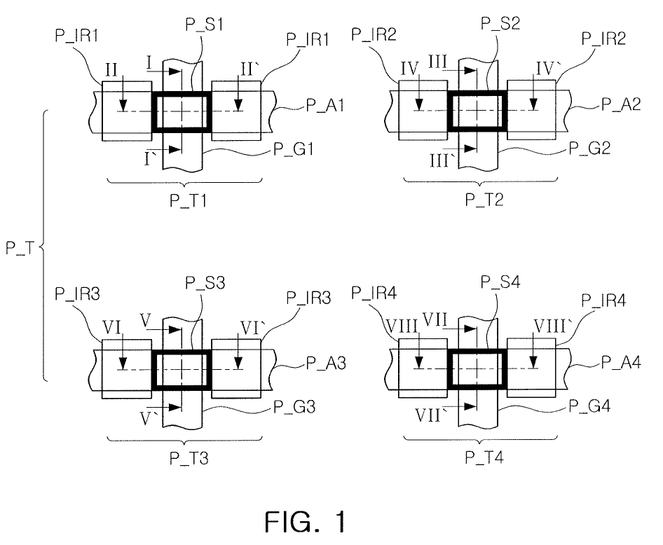

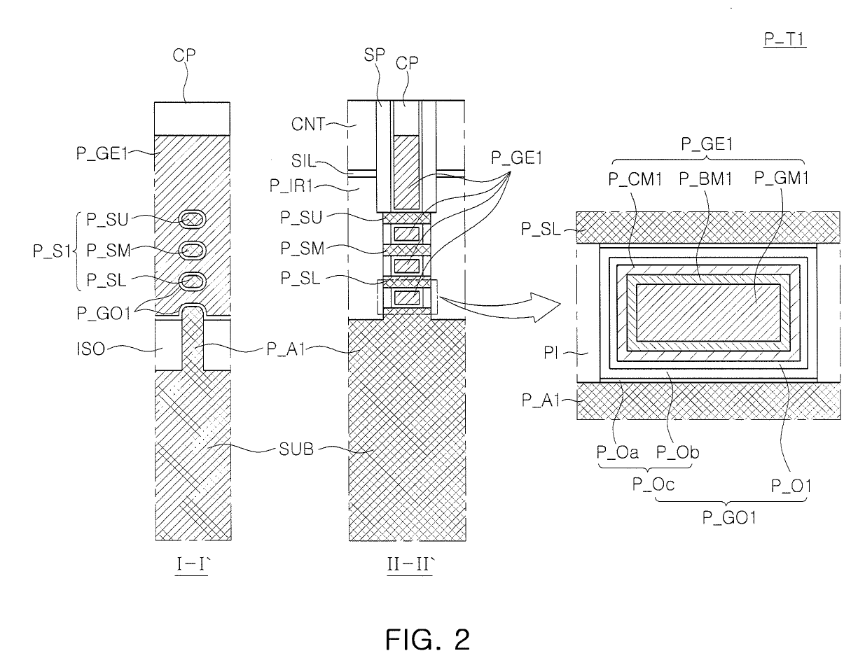

FIG. 1 is a plan view of a semiconductor device according to an example embodiment.

With reference to FIG. 1, a semiconductor device according to an example embodiment may include a plurality of PMOS transistors P_T. The plurality of PMOS transistors P_T may include PMOS transistors having different threshold voltages. For example, the plurality of PMOS transistors P_T may include a first PMOS transistor P_T1, a second PMOS transistor P_T2, a third PMOS transistor P_T3, and a fourth PMOS transistor P_T4. Among the plurality of PMOS transistors P_T, the PMOS transistors having different threshold voltages may include different gate dielectric structures.

The semiconductor device according to an example embodiment may include two or more PMOS transistors having different threshold voltages among the plurality of PMOS transistors P_T.

The semiconductor device according to an example embodiment may include the first PMOS transistor P_T1 and the second PMOS transistor P_T2.

The semiconductor device according to an example embodiment may include the first PMOS transistor P_T1, the fourth PMOS transistor P_T4, and one of the second PMOS transistor P_T2 and the third PMOS transistor P_T3.

The semiconductor device according to an example embodiment may include the first to fourth PMOS transistors P_T1, P_T2, P_T3, and P_T4.

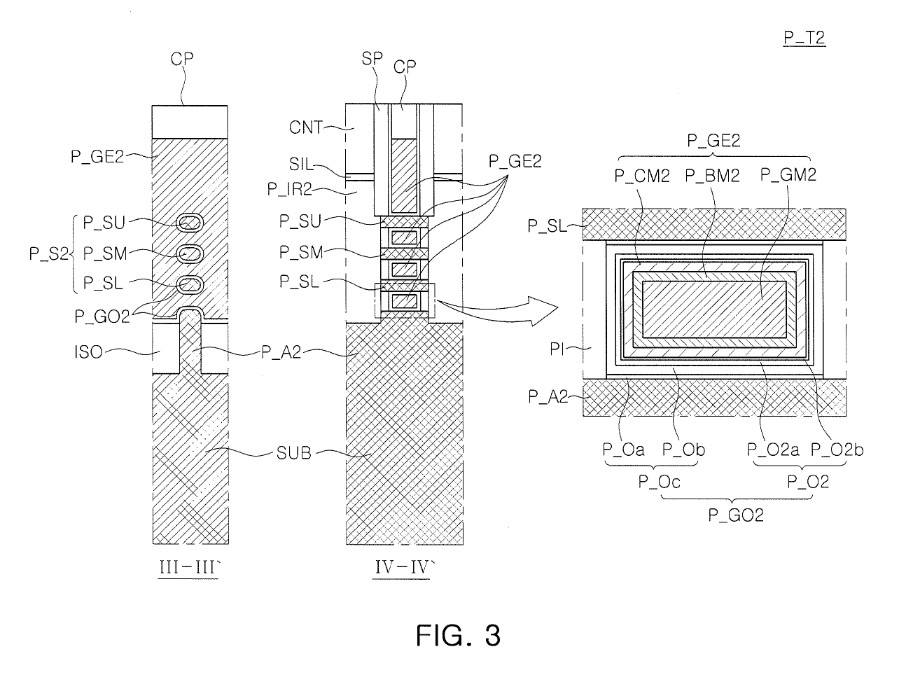

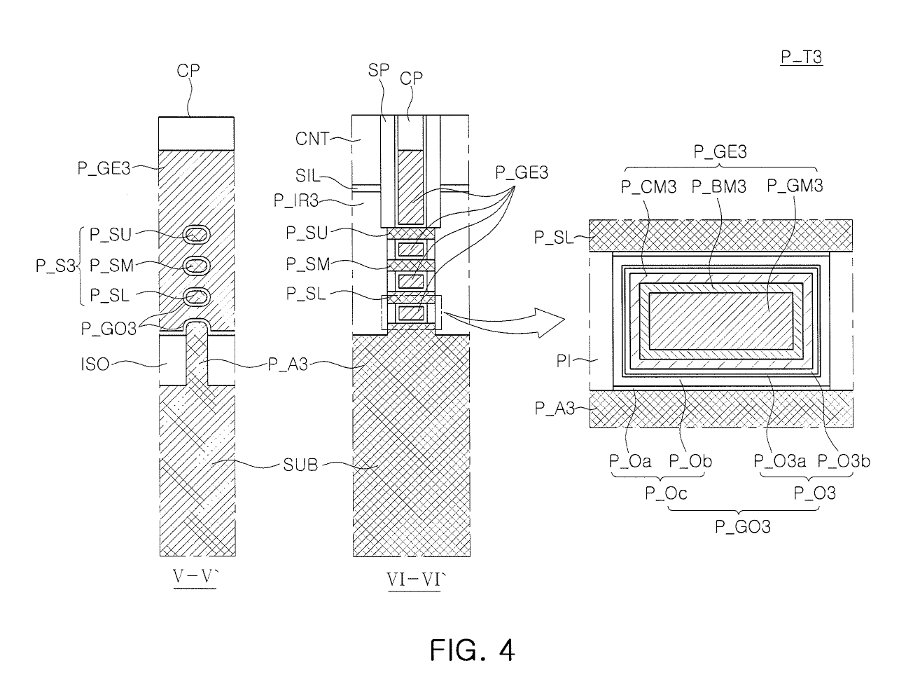

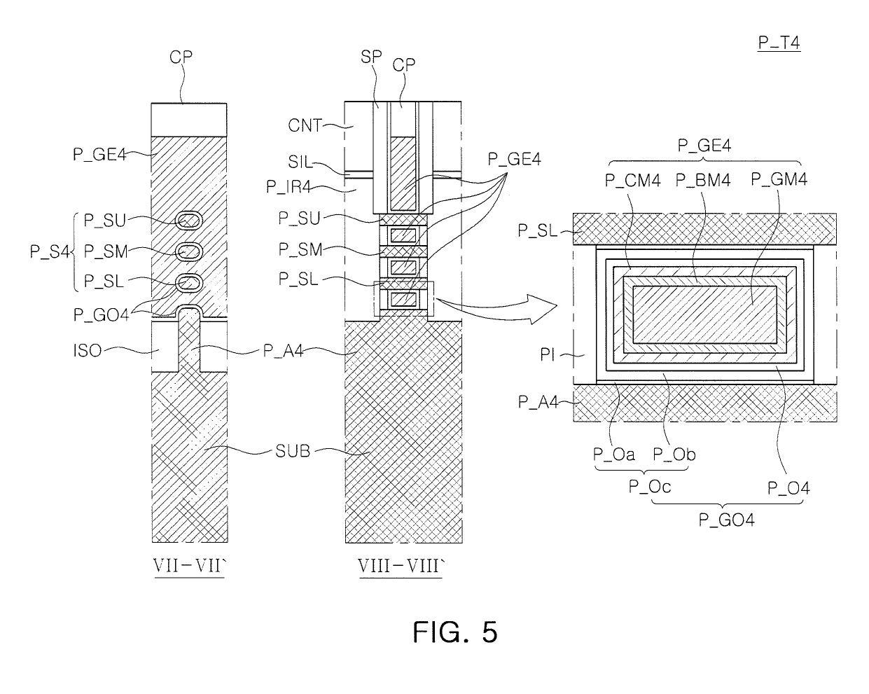

A description of the semiconductor device including each of the first to fourth PMOS transistors P_T1, P_T2, P_T3, and P_T4 will be provided with reference to FIGS. 1, 2, 3, 4, and 5. In FIGS. 2 to 5. FIG. 2 is a cross-sectional view taken along lines I-I′ and II-II′ of FIG. 1; FIG. 3 is a cross-sectional view taken along lines and IV-IV′ of the FIG. 1; FIG. 4 is a cross-sectional view taken along lines V-V′ and VI-VI′ of FIG. 1; and FIG. 5 is a cross-sectional view taken along lines VII-VII′ and VIII-VIII′ of FIG. 1.

First, with reference to FIGS. 1 and 2, a description of the semiconductor device including the first PMOS transistor P_T1 will be provided.

With reference to FIGS. 1 and 2, the first PMOS transistor P_T1 may be disposed on a semiconductor substrate SUB.

The first PMOS transistor P_T1 may include first PMOS source/drain regions P_IR1 disposed on a first PMOS semiconductor pattern P_A1, a first PMOS vertical structure P_S1 disposed on the first PMOS semiconductor pattern P_A1 and disposed between the first PMOS source/drain regions P_IR1, and a first PMOS gate P_G1 intersecting the first PMOS semiconductor pattern P_A1 and the first PMOS vertical structure P_S1.

The first PMOS semiconductor pattern P_A1 may be disposed on the semiconductor substrate SUB. The first PMOS semiconductor pattern P_A1 may have a line shape extended in a first direction X. The first PMOS semiconductor pattern P_A1 may have n-type conductivity. The first PMOS semiconductor pattern P_A1 may be limited by an isolation region ISO disposed on the semiconductor substrate SUB. The isolation region ISO may include an insulating material, such as a silicon oxide, or the like.

The first PMOS source/drain regions P_IR1 may be referred to as an impurity region. The first PMOS source/drain regions P_IR1 may include a semiconductor material (such as silicon (Si), or the like) formed using, for example, a selective epitaxial growth (SEG) method. The semiconductor material formed using the SEG method may be doped with an impurity through, for example, an in-situ process or an ion implantation process. The first PMOS source/drain regions P_IR1 may have p-type conductivity.

As shown in FIG. 2, the first PMOS vertical structure P_S1 may include a first PMOS semiconductor layer P_SL, a second PMOS semiconductor layer P_SM, and a third PMOS semiconductor layer P_SU, disposed in a direction perpendicular to the first PMOS semiconductor pattern P_A1 in sequence and spaced apart from each other in a third direction Z. The first PMOS vertical structure P_S1 may be connected to the first PMOS source/drain regions P_IR1, and may be disposed spaced apart from the first PMOS semiconductor pattern P_A1. The first to third PMOS semiconductor layers P_SL, P_SM, and P_SU may be disposed between the first PMOS source/drain regions P_IR1, and may be connected to or in contact with the first PMOS source/drain regions P_IR1. The first to third PMOS semiconductor layers P_SL, P_SM, and P_SU may have n-type conductivity.

The first PMOS gate P_G1 may include a first PMOS gate dielectric structure P_GO1 and a first PMOS gate electrode structure P_GE1 disposed on the first PMOS gate dielectric structure P_GO1.

The first PMOS gate electrode structure P_GE1 may have a line shape extended in a second direction Y, perpendicular to the first direction X. The first PMOS gate electrode structure P_GE1 may intersect the first PMOS semiconductor pattern P_A1 and the first PMOS vertical structure P_S1. The first PMOS gate electrode structure P_GE1 may be disposed to surround the first to third PMOS semiconductor layers P_SL, P_SM, and P_SU of the first PMOS vertical structure P_S1, and may be disposed to intersect the first PMOS vertical structure P_S1.

The first PMOS gate electrode structure P_GE1 may include a first PMOS capping layer P_CM1, a first PMOS barrier layer P_BM1 on the first PMOS capping layer P_CM1, and a first PMOS low resistance layer P_GM1 on the first PMOS barrier layer P_BM1. The first PMOS capping layer P_CM1 may be provided as a work function metal layer. For example, the first PMOS capping layer P_CM1 may be formed using a metallic nitride, such as a titanium nitride (TiN), a tantalum nitride (TaN), a titanium oxygen nitrogen (TiON), a titanium silicide nitride (TiSiN), or the like. The first PMOS barrier layer P_BM1 may be formed using a metallic nitride, such as TiN, TaN, or the like. The first PMOS low resistance layer P_GM1 may be formed using a metal, such as tungsten (W), or the like.

The first PMOS gate dielectric structure P_GO1 may be disposed between the first PMOS gate electrode structure P_GE1 and the first PMOS semiconductor pattern P_A1, and may be disposed between the first PMOS gate electrode structure P_GE1 and the first PMOS vertical structure P_S1. In addition, between the first PMOS source/drain regions P_IR1, the first PMOS gate dielectric structure P_GO1 may be disposed to surround the first PMOS gate electrode structure P_GE1 disposed between the first PMOS semiconductor pattern P_A1 and the first PMOS semiconductor layer P_SL, to surround the first PMOS gate electrode structure P_GE1 disposed between the first PMOS semiconductor layer P_SL and the second PMOS semiconductor layer P_SM, and to surround the first PMOS gate electrode structure P_GE1 disposed between the second PMOS semiconductor layer P_SM and the third PMOS semiconductor layer P_SU.

The first PMOS gate dielectric structure P_GO1 may include a PMOS common dielectric structure P_Oc and a first PMOS dielectric structure P_O1 on the PMOS common dielectric structure P_Oc.

The PMOS common dielectric structure P_Oc may include a PMOS interface dielectric P_Oa and a PMOS common high-k dielectric P_Ob. The PMOS interface dielectric P_Oa may be disposed between the PMOS common high-k dielectric P_Ob and the first PMOS semiconductor pattern P_A1, and may be disposed between the PMOS common high-k dielectric P_Ob and the first PMOS vertical structure P_S. The PMOS interface dielectric P_Oa may include a Si-based dielectric, such as a Si oxide. The PMOS common high-k dielectric P_Ob may include a hafnium (Hf)-based dielectric, such as a Hf oxide.

The first PMOS dielectric structure P_O1 may include an upper dielectric. The first PMOS dielectric structure P_O1 may include an aluminum (Al)-based dielectric, such as an Al oxide.

In an example embodiment, the first PMOS dielectric structure P_O1 may be formed to have a single layer. For example, the first PMOS dielectric structure P_O1 may be formed to have a single layer including an Al oxide on the PMOS common high-k dielectric P_Ob.

Protective insulating layers PI may be disposed between the first PMOS semiconductor pattern P_A1 and the first PMOS semiconductor layer P_SL, may be disposed between the first PMOS semiconductor layer P_SL and the second PMOS semiconductor layer P_SM, and may be disposed between the second PMOS semiconductor layer P_SM and the third PMOS semiconductor layer P_SU. The protective insulating layer PI may be disposed between the first PMOS gate P_G1 and the first PMOS source/drain regions P_IR1. A gate capping pattern CP having electrical insulating properties may be disposed on the first PMOS gate electrode structure P_GE1. A gate spacer SP having electrical insulating properties may be disposed on a side surface of the gate capping pattern CP. The gate spacer SP may be extended in a lateral direction of a gate electrode structure P_GE1 disposed between the third PMOS semiconductor layer P_U and the gate capping pattern CP. A metallic silicide layer SIL and a conductive contact structure CNT may be disposed on the first PMOS source/drain regions P_IR1, in sequence.

Next, with reference to FIGS. 1 and 3, a description of a semiconductor device including the second PMOS transistor P_T2 will be provided.

With reference to FIGS. 1 and 3, the second PMOS transistor P_T2 may be disposed on the semiconductor substrate SUB.

The second PMOS transistor P_T2 may include a second PMOS semiconductor pattern P_A2, second PMOS source/drain regions P_IR2, and a second PMOS vertical structure P_S2, respectively corresponding to the first PMOS semiconductor pattern (see P_A1 in FIG. 2), the first PMOS source/drain regions (see P_IR1 in FIG. 2), and the first PMOS vertical structure (see P_S1 in FIG. 2), in the first PMOS transistor (see P_T1 in FIG. 2). The second PMOS transistor P_T2 may include the second PMOS semiconductor pattern P_A2 and a second PMOS gate P_G2 intersecting the second PMOS vertical structure P_S2.

The second PMOS gate P_G2 may include a second PMOS gate dielectric structure P_GO2 and a second PMOS gate electrode structure P_GE2 on the second PMOS gate dielectric structure P_GO2. The second PMOS gate electrode structure P_GE2 may include a second PMOS capping layer P_CM2, a second PMOS barrier layer P_BM2 on the second PMOS capping layer P_CM2, and a second PMOS low resistance layer P_GM2 on the second PMOS barrier layer P_BM2.

The second PMOS gate dielectric structure P_GO2 may be disposed between the second PMOS gate electrode structure P_GE2 and the second PMOS semiconductor pattern P_A2, may be disposed between the second PMOS gate electrode structure P_GE2 and the second PMOS vertical structure P_S2.

The second PMOS gate dielectric structure P_GO2 may include a PMOS common dielectric structure P_Oc and a second PMOS dielectric structure P_O2 on the PMOS common dielectric structure P_Oc.

The PMOS common dielectric structure P_Oc may include the same material, and may have the same structure as the PMOS common dielectric structure P_Oc of the first PMOS transistor P_T1. For example, the PMOS common dielectric structure P_Oc may include the PMOS interface dielectric PO_a and the PMOS common high-k dielectric P_Ob.

The second PMOS dielectric structure P_O2 may include a first upper dielectric P_O2a and a second upper dielectric P_O2b.

In an example embodiment, the first upper dielectric P_O2a may be disposed between the second upper dielectric P_O2b and the second PMOS gate electrode structure P_GE2.

In an example embodiment, the second upper dielectric P_O2b may have a thickness less than that of the first upper dielectric P_O2a.

In an example embodiment, the first upper dielectric P_O2a may include an Al-based dielectric, such as an Al oxide, while the second upper dielectric P_O2b may be formed to have a dipole layer. The dipole layer may include a La-based dielectric, such as a lanthanum (La) oxide, or may include a Mg-based dielectric, such as a Mg oxide.

The protective insulating layers PI, the gate capping pattern CP, the gate spacer SP, the metallic silicide layer SIL, and the contact structure CNT, as illustrated in FIG. 2, may be disposed.

Subsequently, with reference to FIGS. 1 and 4, a description of a semiconductor device including the third PMOS transistor P_T3 will be provided.

With reference to FIGS. 1 and 4, the third PMOS transistor P_T3 may be disposed on the semiconductor substrate SUB.

The third PMOS transistor P_T3 may include a third PMOS semiconductor pattern P_A3, a third PMOS source/drain regions P_IR3, and a third PMOS vertical structure P_S3, respectively corresponding to the first PMOS semiconductor pattern (see P_A1 in FIG. 2), the first PMOS source/drain regions (see P_IR1 in FIG. 2), and the first PMOS vertical structure (see P_S1 in FIG. 2), in the first PMOS transistor (see P_T1 in FIG. 2).

The third PMOS transistor P_T3 may include the third PMOS semiconductor pattern P_A3 and a third PMOS gate P_G3 intersecting the third PMOS vertical structure P_S3. The third PMOS gate P_G3 may include a third PMOS gate dielectric structure P_GO3 and a third PMOS gate electrode structure P_GE3 on the third PMOS gate dielectric structure P_GO3.

The third PMOS gate electrode structure P_GE3 may include a third PMOS capping layer P CM3, a third PMOS barrier layer P_BM3 on the third PMOS capping layer P_CM3, and a third PMOS low resistance layer P_GM3 on the third PMOS barrier layer P_BM3.

The third PMOS gate dielectric structure P_GO3 may be disposed between the third PMOS gate electrode structure P_GE3 and the third PMOS semiconductor pattern P_A3, and may be disposed between the third PMOS gate electrode structure P_GE3 and the third PMOS vertical structure P_S3.

The third PMOS gate dielectric structure P_GO3 may include a PMOS common dielectric structure P_Oc and a third PMOS dielectric structure P_O3 on the PMOS common dielectric structure P_Oc.

The PMOS common dielectric structure P_Oc may include the same material, and may have the same structure as those of the PMOS common dielectric structure P_Oc of the first PMOS transistor P_T1. For example, the PMOS common dielectric structure P_Oc may include the PMOS interface dielectric 130a and the PMOS common high-k dielectric P_Ob.

The third PMOS dielectric structure P_O3 may include a mixture of a first upper dielectric P_O3a and a second upper dielectric P_O3b.

In an example embodiment, the first upper dielectric P_O3a may be disposed between the second upper dielectric P_O3b and the third PMOS gate electrode structure P_GE3.

In an example embodiment, the first upper dielectric P_O3a of the third PMOS dielectric structure P_O3 may include the same material as that of the first upper dielectric P_O2a of the second PMOS dielectric structure P_O2. In addition, the second upper dielectric P_O3b of the third PMOS dielectric structure P_O3 may include the same material as that of the second upper dielectric P_O2b of the second PMOS dielectric structure P_O2.

In an example embodiment, the first upper dielectric P_O3a may include an Al-based high-k dielectric, such as an Al oxide, while the second upper dielectric P_O3b may be formed to have a dipole layer. The dipole layer may be provided as a La-based dielectric, such as a La oxide, or may be provided as a Mg-based dielectric, such as a Mg oxide.

In an example embodiment, a portion of the first upper dielectric in the first and second upper dielectrics in the third PMOS dielectric structure P_O3 may be different from the portion of the first upper dielectric in the first and second upper dielectrics in the second PMOS dielectric structure (see P_O2 in FIG. 3). A portion of the second upper dielectric P_O2b in the second PMOS dielectric structure (see P_O2 in FIG. 3) may be different from the portion of the second upper dielectric P_O3b in the third PMOS dielectric structure P_O3. For example, the first upper dielectric P_O2a may have a width greater than that of the second upper dielectric P_O2b in the second PMOS dielectric structure P_O2 (see P_O2 in FIG. 3). In the meantime, the first upper dielectric P_O3a may have a width less than that of the second upper dielectric P_O3b in the third PMOS dielectric structure P_O3.

The protective insulating layers PI, the gate capping pattern CP, the gate spacer SP, the metallic silicide layer SIL, and the contact structure CNT, as illustrated in FIG. 2, may be disposed.

In an example embodiment, a distance between the second upper dielectrics P_O2b and P_O3b and the gate electrode structures P_GE2 and P_GE3 is smaller than the distance between the first upper dielectrics P_O2a and P_O3a and the gate electrode structures P_GE2 and P_GE3, in the second PMOS transistor P_T2 and the third PMOS transistor P_T3. However, the distance between the first upper dielectrics P_O2a and P_O3a and the gate electrode structures P_GE2 and P_GE3 may be smaller than the distance between the second upper dielectrics P_O2b and P_O3b and the gate electrode structures P_GE2 and P_GE3, in the second PMOS transistor P 12 and the third PMOS transistor P_T3.

With reference to FIGS. 1 and 5, the description of the semiconductor device including the fourth PMOS transistor P_T4 will be provided.

With reference to FIGS. 1 and 5, the fourth PMOS transistor P_T4 may be disposed on the semiconductor substrate SUB.

The fourth PMOS transistor P_T4 may include a fourth PMOS semiconductor pattern P_A4, a fourth PMOS source/drain regions P_IR4, and a fourth PMOS vertical structure P_S4, respectively corresponding to the first PMOS semiconductor pattern (see P_A1 in FIG. 2), the first PMOS source/drain regions (see P_IR1 in FIG. 2), and the first PMOS vertical structure (see P_S1 in FIG. 2), in the first PMOS transistor (see P_T1 in FIG. 2).

The fourth PMOS transistor P_T4 may include the fourth PMOS semiconductor pattern P_A4 and a fourth PMOS gate P_G4 intersecting the fourth PMOS vertical structure P_S4. The fourth PMOS gate P_G4 may include a fourth PMOS gate dielectric structure P_GO4 and a fourth PMOS gate electrode structure P_GE4 on the fourth PMOS gate dielectric structure P_GO4.

The fourth PMOS gate electrode structure P_GE4 may intersect the fourth PMOS semiconductor pattern P_A4 and the fourth PMOS vertical structure P_S4. The fourth PMOS gate electrode structure P_GE4 may include a fourth PMOS capping layer P_CM4, a fourth PMOS barrier layer P_BM4 on the fourth PMOS capping layer P_CM4, and a fourth PMOS low resistance layer P_GM4 on the fourth PMOS barrier layer P_BM4.

The fourth PMOS gate dielectric structure P_GO4 may be disposed between the fourth PMOS gate electrode structure P_GE4 and the fourth PMOS semiconductor pattern P_A4, and may be disposed between the fourth PMOS gate electrode structure P_GE4 and the fourth PMOS vertical structure P_S4.

The fourth PMOS gate dielectric structure P_GO4 may include a PMOS common dielectric structure P_Oc and a fourth PMOS dielectric structure P_O4 on the PMOS common dielectric structure P_Oc. The PMOS common dielectric structure P_Oc may include the same material, and may have the same structure as those of the PMOS common dielectric structure P_Oc of the first PMOS transistor (see P_T1 in FIG. 2). For example, the PMOS common dielectric structure P_Oc may include the PMOS interface dielectric P_Oa and the PMOS common high-k dielectric P_Ob.

The fourth PMOS dielectric structure P_O4 may include a second upper dielectric including a material different from that of the first upper dielectric of the first PMOS dielectric structure (see P_O1 in FIG. 2).

The second upper dielectric of the fourth PMOS dielectric structure P_O4 may be provided as a dipole layer. The dipole layer may include a La-based dielectric, such as a La oxide, or may include a Mg-based dielectric, such as a Mg oxide.

In an example embodiment, the fourth PMOS dielectric structure P_O4 may be formed to have a single layer. For example, the fourth PMOS dielectric structure P_O4 may be formed to have a single layer, a dipole layer.

The protective insulating layers PI, the gate capping pattern CP, the gate spacer SP, the metallic silicide layer SIL, and the contact structure CNT, as illustrated in FIG. 2, may be disposed.

In the first to fourth PMOS transistors P_T1, P_T2, P_T3, and P_T4, the first to fourth PMOS gate dielectric structures P_GO1, P_GO2, P_GO3, and P_GO4 may have the common dielectric structure P_Oc in common.

In addition, the first to fourth PMOS gate dielectric structures P_GO1, P_GO2, P_GO3, and P_GO4 may include at least one of a first shifter and a second shifter, enabling threshold voltages of the first to fourth PMOS transistors P_T1, P_T2, P_T3, and P_T4 to be different. For example, between the first PMOS transistor P_T1 and the fourth PMOS transistor P_T4, the threshold voltage of the first PMOS transistor P_T1 including the first PMOS dielectric structure P_O1 formed using the first upper dielectric material (such as an Al oxide (Al₂O₃)) may be lower than that of the fourth PMOS transistor P_T4 including the fourth PMOS dielectric structure P_O4 formed using the second upper dielectric material (such as a La oxide (La₂O₃) or a Mg oxide (MgO)).

Thus, in the above-described structure, the first upper dielectric P_O2a may be referred to as the first shifter, while the second upper dielectric P_O2b may be referred to as the second shifter. The first shifter formed to be the first upper dielectric P_O2a may allow the threshold voltage of a PMOS transistor to decrease, while the second shifter formed to be the second upper dielectric P_O2b may allow the threshold voltage of the PMOS transistor to increase.

In the second PMOS gate dielectric structure P_GO2 and the third PMOS gate dielectric structure P_GO3, the first upper dielectric P_O2a and the first upper dielectric P_O3a may be referred to as the first shifter. In addition, the second upper dielectric P_O2b and the second upper dielectric P_O3b may be referred to as the second shifter. The first upper dielectric P_O2a and the first upper dielectric P_O3a may act as the first shifter, and may include an Al-based dielectric, such as an Al oxide. The second upper dielectric P_O2b and the second upper dielectric P_O3b may act as the second shifter, and may include a material forming the dipole layer, such as a La-based dielectric or a Mg-based dielectric.

The threshold voltage of the second PMOS transistor P_T2 may be different from that of the third PMOS transistor P_T3 by allowing a portion of the second upper dielectric P_O2b in the second PMOS gate dielectric structure P_GO2 to be different from the portion of the second upper dielectric P_O3b in the third PMOS gate dielectric structure P_GO3. For example, the second upper dielectric P_O2b in the second PMOS gate dielectric structure P_GO2 may be formed to have a thickness less than that of the second upper dielectric P_O2b in the third PMOS gate dielectric structure P_GO3.

In addition, the first to fourth PMOS transistors P_T1, P_T2, P_T3, and P_T4 may include gate dielectric structures having different structures. Therefore, the first to fourth PMOS transistors P_T1, P_T2, P_T3, and P_T4 may be disposed to have different threshold voltages.

<<Semiconductor Device with a Plurality of NMOS Transistors>>

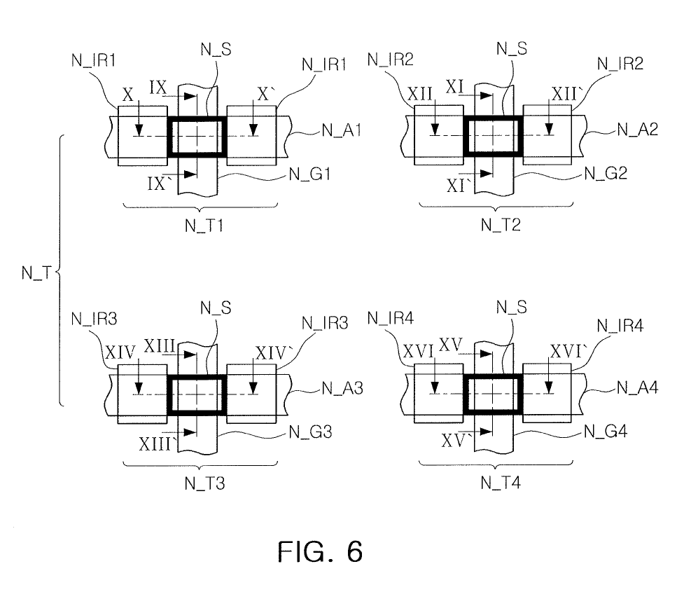

FIG. 6 is a plan view of a semiconductor device according to an example embodiment. A description of the semiconductor device according to an example embodiment will be provided with reference to FIG. 6.

With reference to FIG. 6, the semiconductor device according to an example embodiment may include a plurality of NMOS transistors N_T. The plurality of NMOS transistors N_T may include the NMOS transistors having different threshold voltages. For example, the plurality of NMOS transistors N_T may include a first NMOS transistor N_T1, a second NMOS transistor N_T2, a third NMOS transistor N_T3, and a fourth NMOS transistor N_T4. Among the plurality of NMOS transistors N_T, the NMOS transistors having different threshold voltages may include different gate dielectric structures.

The semiconductor device according to an example embodiment may include one or more NMOS transistors having different threshold voltages among the plurality of NMOS transistors N_T.

The semiconductor device according to an example embodiment may include the first NMOS transistor N_T1 and the second NMOS transistor N_T2.

The semiconductor device according to an example embodiment may include the first NMOS transistor N_T1 and the fourth NMOS transistor N_T4 and one of the second NMOS transistor N_T2 and the third NMOS transistor N_T3.

The semiconductor device according to an example embodiment may include the first to fourth NMOS transistors N_T1, N_T2, N_T3, and N_T4.

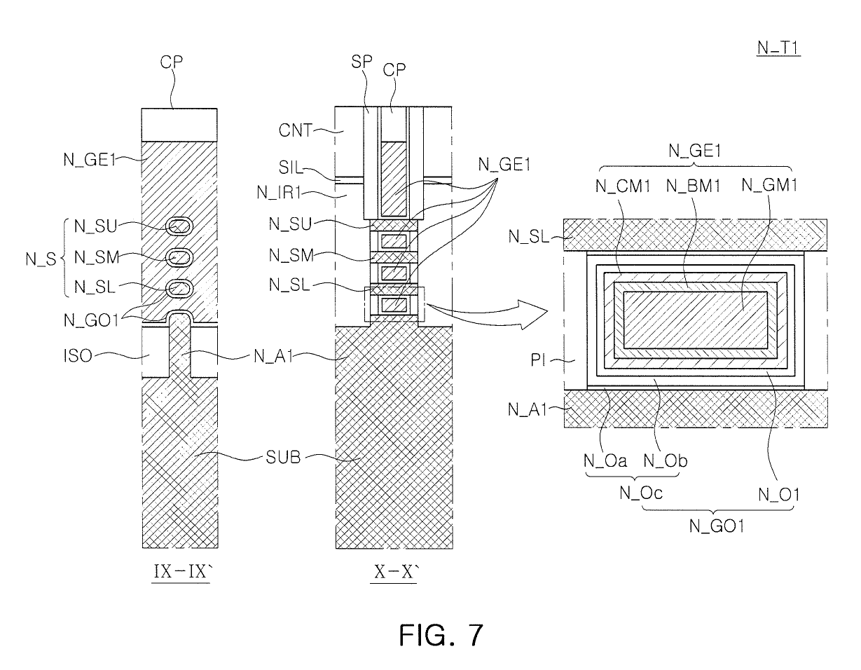

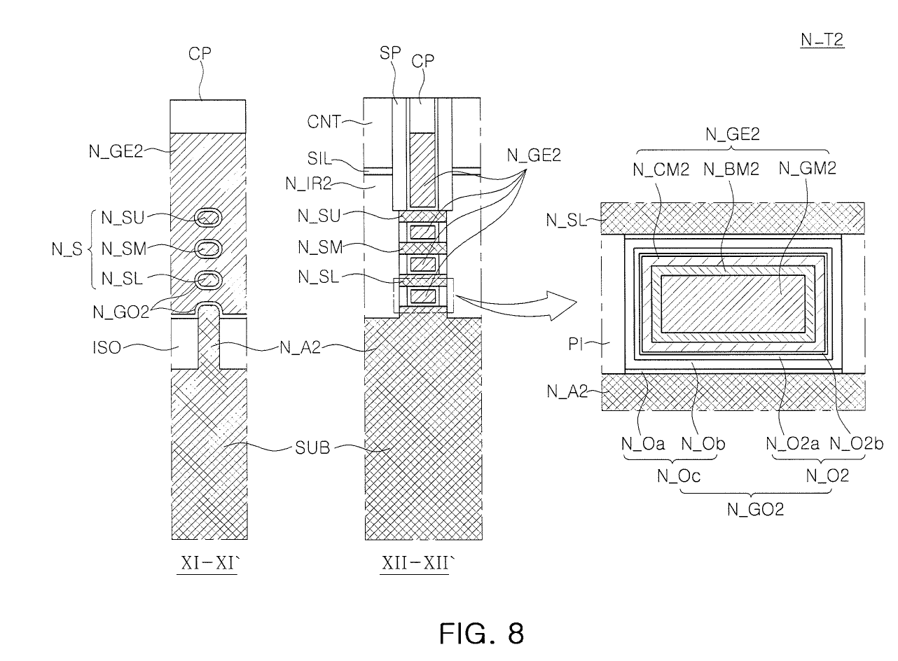

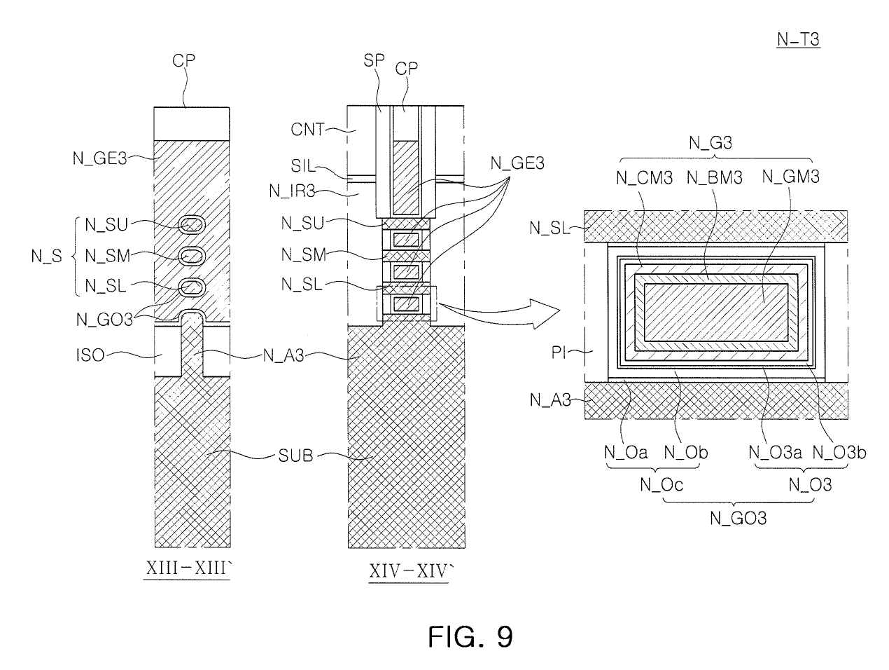

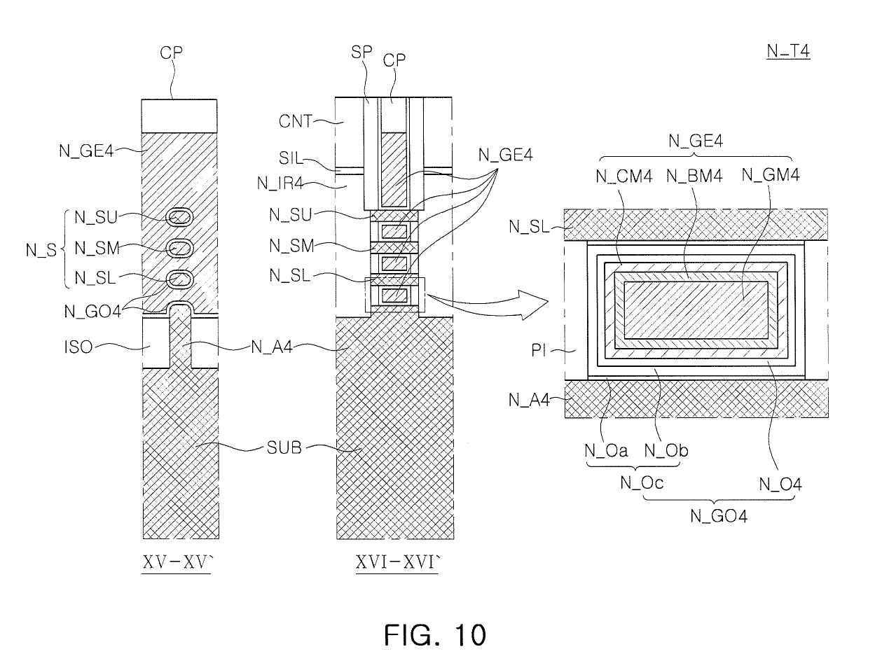

A description of the semiconductor device including each of the first to fourth NMOS transistors N_T1, N_T2, N_T3, and N_T4 will be provided with reference to FIGS. 6, 7, 8, 9, and 10. In FIGS. 7 to 10, FIG. 7 is a cross-sectional view taken along lines IX-IX′ and X-X′ of FIG. 6, FIG. 8 is a cross-sectional view taken along lines XI-XI′ and XII-XII′ of FIG. 6, FIG. 9 is a cross-sectional view taken along lines XIII-XIII′ and XIV-XIV′ of FIG. 6, and FIG. 10 is a cross-sectional view taken along lines XV-XV′ and XVI-XVI′ of FIG. 6.

First, with reference to FIGS. 6 and 7, a description of the semiconductor device including the first NMOS transistor N_T1 will be provided.

With reference to FIGS. 6 and 7, the first NMOS transistor N_T1 may be disposed on a semiconductor substrate SUB.

The first NMOS transistor N_T1 may include first NMOS source/drain regions N_IR1 disposed on a first NMOS semiconductor pattern N_A1, a first NMOS vertical structure N_S1 disposed on the first NMOS semiconductor pattern N_A1 and disposed between the first NMOS source/drain regions N_IR1, and a first NMOS gate N_G1 interacting with the first NMOS semiconductor pattern N_A1 and the first NMOS vertical structure N_S1.

The first NMOS semiconductor pattern N_A1 is disposed on the semiconductor substrate SUB, and may be limited by an isolation region ISO disposed on the semiconductor substrate SUB. The first NMOS semiconductor pattern N_A1 may have a line shape extended in a first direction X. The first NMOS semiconductor pattern N_A1 may have p-type conductivity. The isolation region ISO may include an insulating material, such as a Si oxide, or the like.

The first NMOS source/drain regions N_IR1 may be referred to as an impurity region. The first NMOS source/drain regions N_IR1 may be formed of a semiconductor material (such as Si, silicon carbide (SiC), or the like) formed using, for example, a selective epitaxial growth (SEG) method. In addition, the semiconductor material formed using the SEG method may be doped with an impurity through an in-situ process or an ion implantation process. The first NMOS source/drain regions N_IR1 may have n-type conductivity.

The first NMOS vertical structure N_S1 may include a first NMOS semiconductor layer N_SL, a second NMOS semiconductor layer N_SM, and a third NMOS semiconductor layer N_SU, disposed in a direction perpendicular to the first NMOS semiconductor pattern N_A1 in sequence and disposed spaced apart from each other. The first NMOS vertical structure N_S1 may be connected to the first NMOS source/drain regions N_IR1, and may be disposed to be spaced from the first NMOS semiconductor pattern N_A1. The first to third NMOS semiconductor layers N_SL, N_SM, and N_SU may be disposed between the first NMOS source/drain regions N_IR1, and may be connected to or in contact with the first NMOS source/drain regions N_IR1. The first to third NMOS semiconductor layers N_SL, N_SM, and N_SU may have p-type conductivity.

The first NMOS gate N_G1 may include a first NMOS gate dielectric structure N_GO1 and a first NMOS gate electrode structure N_GE1 on the first NMOS gate dielectric structure N_GO1.

The first NMOS gate electrode structure N_GE1 may have a line shape extended in a second direction Y, perpendicular to the first direction X. The first NMOS gate electrode structure N_GE1 may be disposed to surround the first to third NMOS semiconductor layers N_SL, N_SM, and N_SU, and may be disposed to intersect the first NMOS vertical structure N_S1. The first NMOS gate electrode structure N_GE1 may include a first NMOS capping layer N_CM1, a first NMOS barrier layer N_BM1 on the first NMOS capping layer N_CM1, and a first NMOS low resistance layer N_GM1 on the first NMOS barrier layer N_BM1. The first NMOS barrier layer N_BM1 may be formed using a metallic nitride, such as TiN, TaN, or the like. The first NMOS low resistance layer N_GM1 may be formed using a metal, such as W, or the like.

In an example embodiment, the first NMOS capping layer N_CM1 may have a different structure or may include a different material from that of the first PMOS capping layer (see P_CM1 in FIG. 2). For example, the first NMOS capping layer N_CM1 may be formed to have a single form or a mixed layer using TiN, TaN, TiON or TiSiN.

The first NMOS gate dielectric structure N_GO1 may be disposed between the first NMOS gate electrode structure N_GE1 and the first NMOS semiconductor pattern N_A1, and may be disposed between the first NMOS gate electrode structure N_GE1 and the first NMOS vertical structure N_S1. Between the first NMOS source/drain regions N_IR1, the first NMOS gate dielectric structure N_GO1 may be disposed to surround a portion of the first NMOS gate electrode structure N_GE1 disposed between the first NMOS semiconductor pattern N_A1 and the first NMOS semiconductor layer N_SL, a portion of the first NMOS gate electrode structure N_GE1 disposed between the first NMOS semiconductor layer N_SL and the second NMOS semiconductor layer N_SM, and a portion of the first NMOS gate electrode structure N_GE1 disposed between the second NMOS semiconductor layer N_SM and the third NMOS semiconductor layer N_SU.

The first NMOS gate dielectric structure N_GO1 may include an NMOS common dielectric structure N_Oc and a first NMOS dielectric structure N_O1 on the NMOS common dielectric structure N_Oc.

The NMOS common dielectric structure N_Oc may include an NMOS interface dielectric N_Oa and an NMOS common high-k dielectric N_Ob. The NMOS interface dielectric N_Oa may be disposed between the NMOS common high-k dielectric N_Ob and the first NMOS semiconductor pattern N_A1, and may be disposed between the NMOS common high-k dielectric N_Ob and the first NMOS vertical structure N_S1. The NMOS interface dielectric N_Oa may include a Si oxide. The NMOS common high-k dielectric N_Ob may include an Hf-based dielectric, such as an Hf oxide.

The first NMOS dielectric structure N_O1 may include an upper dielectric formed using an upper dielectric material.

In an example embodiment, the first NMOS dielectric structure N_O1 may include the same material as that of the fourth PMOS dielectric structure (see P_O4 in FIG. 5) of the fourth PMOS gate dielectric structure (see P_GO4 in FIG. 5). For example, in the case that the second upper dielectric of the fourth PMOS dielectric structure (see P_O4 in FIG. 5) is formed to have a dipole layer, the first NMOS dielectric structure N_O1 may be formed to have the dipole layer. The dipole layer may include a La-based dielectric, such as a La oxide, or may include a Mg-based dielectric, such as a Mg oxide.

In an example embodiment, the first NMOS dielectric structure N_O1 may be formed to have a single layer. For example, the first NMOS dielectric structure N_O1 may be formed to have a single layer including the dipole layer on the NMOS common dielectric N_Ob.

Protective insulating layers PI may be disposed between the first NMOS semiconductor pattern N_A1 and the first NMOS semiconductor layer N_SL, may be disposed between the first NMOS semiconductor layer N_SL and the second NMOS semiconductor layer N_SM, and may be disposed between the second NMOS semiconductor layer N_SM and the third NMOS semiconductor layer N_SU. The protective insulating layer PI may be disposed between the first NMOS gate N_G1 and the first NMOS source/drain regions N_IR1.

A gate capping pattern CP having electrical insulating properties may be disposed on the first NMOS gate electrode structure N_GE1. A gate spacer SP having electrical insulating properties may be disposed on a side surface of the gate capping pattern CP. The gate spacer SP may be extended in a lateral direction of a gate electrode structure N_GE1 disposed between the third NMOS semiconductor layer N_U and the gate capping pattern CP. A metallic silicide layer SIL and a conductive contact structure CNT may be disposed on the first NMOS source/drain regions N_IR1 in sequence.

Next, with reference to FIGS. 6 and 8, a description of the semiconductor device including the second NMOS transistor N_T2 will be provided.

With reference to FIGS. 6 and 8, the second NMOS transistor N_T2 may be disposed on the semiconductor substrate SUB.

The second NMOS transistor N_T2 may include a second NMOS semiconductor pattern N_A2, a second NMOS source/drain regions N_IR2, and a second NMOS vertical structure N_S2, respectively corresponding to the first NMOS semiconductor pattern (see N_A1 in FIG. 7), the first NMOS source/drain regions (see N_IR1 in FIG. 7), and the first NMOS vertical structure (see N_S1 in FIG. 7), in the first NMOS transistor (see N_T1 in FIG. 7).

The second NMOS transistor N_T2 may include a second NMOS gate N_G2. The second NMOS gate N_G2 may include a second NMOS gate dielectric structure N_GO2 and a second NMOS gate electrode structure N_GE2 on the second NMOS gate dielectric structure N_GO2. The second NMOS gate electrode structure N_GE2 may intersect the second NMOS semiconductor pattern N_A2 and the second NMOS vertical structure N_S2. The second NMOS gate electrode structure N_GE2 may include a second NMOS capping layer N_CM2, a second NMOS barrier layer N_BM2 on the second NMOS capping layer N_CM2, and a second NMOS low resistance layer N_GM2 on the second NMOS barrier layer N_BM2.

The second NMOS gate dielectric structure N_GO2 may be disposed between the second NMOS gate electrode structure N_GE2 and the second NMOS semiconductor pattern N_A2, and may be disposed between the second NMOS gate electrode structure N_GE2 and the second NMOS vertical structure N_S2.

The second NMOS gate dielectric structure N_GO2 may include an NMOS common dielectric structure N_Oc and a second NMOS dielectric structure N_O2 on the NMOS common dielectric structure N_Oc. The NMOS common dielectric structure N_Oc may include the same material, and may have the same structure as those of the NMOS common dielectric structure N_Oc of the first NMOS transistor N_T1. For example, the NMOS common dielectric structure N_Oc may include the NMOS interface dielectric N_Oa and the NMOS common high-k dielectric N_Ob.

The second NMOS dielectric structure N_O2 may include a mixture of a second upper dielectric N_O2a and a first upper dielectric N_O2b. The second upper dielectric N_O2a may be disposed between the first upper dielectric N_O2b and the second NMOS gate electrode structure N_GE2. The first upper dielectric N_O2b may have a thickness less than that of the second upper dielectric N_O2a.

In an example embodiment, the second upper dielectric N_O2a may include an Al-based high-k dielectric, such as an Al oxide. The first upper dielectric N_O2b may be formed to have a dipole layer. The dipole layer may be provided as a La-based dielectric, such as a La oxide, or may be provided as a Mg-based dielectric, such as a Mg oxide.

The protective insulating layers PI, the gate capping pattern CP, the gate spacer SP, the metallic silicide layer SIL, and the contact structure CNT, as illustrated in FIG. 7, may be disposed.

With reference to FIGS. 6 and 9, a description of the semiconductor device including the third NMOS transistor N_T3 will be provided.

With reference to FIGS. 6 and 9, the third NMOS transistor N_T3 may be disposed on the semiconductor substrate SUB.

The third NMOS transistor N_T3 may include a third NMOS semiconductor pattern N_A3, a third NMOS source/drain regions N_IR3, and a third NMOS vertical structure N_S3, respectively corresponding to the first NMOS semiconductor pattern (see N_A1 in FIG. 7), the first NMOS source/drain regions (see N_IR1 in FIG. 7), and the first NMOS vertical structure (see N_S1 in FIG. 7), in the first NMOS transistor (see N_T1 in FIG. 7).

The third NMOS transistor N_T3 may include a third NMOS gate N_G3. The third NMOS gate N_G3 may include a third NMOS gate dielectric structure N_GO3 and a third NMOS gate electrode structure N_GE3 on the third NMOS gate dielectric structure N_GO3.

The third NMOS gate electrode structure N_GE3 may intersect the third NMOS semiconductor pattern N_A3 and the third NMOS vertical structure N_S3. The third NMOS gate electrode structure N_GE3 may include a third NMOS capping layer N_CM3, a third NMOS barrier layer N_BM3 on the third NMOS capping layer N_CM3, and a third NMOS low resistance layer N_GM3 on the third NMOS barrier layer N_BM3.

The third NMOS gate dielectric structure N_GO3 may be disposed between the third NMOS gate electrode structure N_GE3 and the third NMOS semiconductor pattern N_A3, and may be disposed between the third NMOS gate electrode structure N_GE3 and the third NMOS vertical structure N_S3.

The third NMOS gate dielectric structure N_GO3 may include an NMOS common dielectric structure N_Oc and a third NMOS dielectric structure N_O3 on the NMOS common dielectric structure N_Oc. The NMOS common dielectric structure N_Oc may include the same material, and may have the same structure as those of the NMOS common dielectric structure N_Oc of the first NMOS transistor N_T1.

The third NMOS dielectric structure N_O3 may include a mixture of a second upper dielectric N_O3a and a first upper dielectric N_O3b. The second upper dielectric N_O3a may be disposed between the first upper dielectric N_O3b and the third NMOS gate electrode structure N_GE3. The first upper dielectric N_O3b may have a thickness greater than that of the second upper dielectric N_O3a.

In an example embodiment, the first upper dielectric N_O3b may be formed to have a dipole layer. The dipole layer may be provided as a La-based dielectric, such as a La oxide, or may be provided as a Mg-based dielectric, such as a Mg oxide. The second upper dielectric N_O3a may include an Al-based high-k dielectric, such as an Al oxide.

The protective insulating layers PI, the gate capping pattern CP, the gate spacer SP, the metallic silicide layer SIL, and the contact structure CNT, as illustrated in FIG. 7, may be disposed.

In an example embodiment, a distance between the second upper dielectrics N_O2a and N_O3a and the gate electrode structures N_GE2 and N_GE3 is smaller than the distance between the first upper dielectrics N_O2b and N_O3b and the gate electrode structures N_GE2 and N_GE3, in the second NMOS transistor N_T2 and the third NMOS transistor N_T3. However, the distance between the first upper dielectrics N_O2b and N_O3b and the gate electrode structures N_GE2 and N_GE3 may be smaller than the distance between the second upper dielectrics N_O2a and N_O3a and the gate electrode structures N_GE2 and N_GE3, in the second NMOS transistor N_T2 and the third NMOS transistor N_T3.

With reference to FIGS. 6 and 10, a description of the semiconductor device including the fourth NMOS transistor N_T4 will be provided.

With reference to FIGS. 6 and 10, the fourth NMOS transistor N_T4 may be disposed on the semiconductor substrate SUB.

The fourth NMOS transistor N_T4 may include a fourth NMOS semiconductor pattern N_A4, a fourth NMOS source/drain regions N_IR4, and a fourth NMOS vertical structure N_S4, respectively corresponding to the first NMOS semiconductor pattern (see N_A1 in FIG. 7), the first NMOS source/drain regions (see N_IR1 in FIG. 7), and the first NMOS vertical structure (see N_S1 in FIG. 7), in the first NMOS transistor (see N_T1 in FIG. 7).

The fourth NMOS transistor N_T4 may include a fourth NMOS gate N_G4. The fourth NMOS gate N_G4 may include a fourth NMOS gate dielectric structure N_GO4 and a fourth NMOS gate electrode structure N_GE4 on the fourth NMOS gate dielectric structure N_GO4.

The fourth NMOS gate electrode structure N_GE4 may interact with the fourth NMOS semiconductor pattern N_A4 and the fourth NMOS vertical structure N_S4. The fourth NMOS gate electrode structure N_GE4 may include a fourth NMOS capping layer N_CM4, a fourth NMOS barrier layer N_BM4 on the fourth NMOS capping layer N_CM4, and a fourth NMOS low resistance layer N_GM4 on the fourth NMOS barrier layer N_BM4.

The fourth NMOS gate dielectric structure N_GO4 may be disposed between the fourth NMOS gate electrode structure N_GE4 and the fourth NMOS semiconductor pattern N_A4, and may be disposed between the fourth NMOS gate electrode structure N_GE4 and the fourth NMOS vertical structure N_S4.

The fourth NMOS gate dielectric structure N_GO4 may include an NMOS common dielectric structure N_Oc and a fourth NMOS dielectric structure N_O4 on the NMOS common dielectric structure N_Oc. The NMOS common dielectric structure N_Oc may include the same material, and may have the same structure as those of the NMOS common dielectric structure N_Oc of the first NMOS transistor N_T1. For example, the NMOS common dielectric structure N_Oc may include the NMOS interface dielectric N_Oa and the NMOS common high-k dielectric N_Ob.

The fourth NMOS dielectric structure N_O4 may include an upper dielectric. The upper dielectric of the fourth NMOS dielectric structure N_O4 may be provided as an Al-based high-k dielectric, such as an Al oxide.

In an example embodiment, the fourth NMOS dielectric structure N_O4 may be formed to have a single layer.

The protective insulating layers PI, the gate capping pattern CP, the gate spacer SP, the metallic silicide layer SIL, and the contact structure CNT, as illustrated in FIG. 7, may be disposed.

In the first to fourth NMOS transistors N_T1, N_T2, N_T3, and N_T4, the first to fourth NMOS gate dielectric structures N_GO1, N_GO2, N_GO3, and N_GO4 may include the common dielectric structure N_Oc in common.

In addition, the first to fourth NMOS gate dielectric structures N_GO1, N_GO2, N_GO3, and N_GO4 may include at least one of a first shifter and a second shifter, enabling threshold voltages of the first to fourth NMOS transistors N_T1, N_T2, N_T3, and N_T4 to be different. For example, between the first NMOS transistor N_T1 and the fourth NMOS transistor N_T4, the threshold voltage of the first NMOS transistor N_T1 including the first NMOS dielectric structure N_O1 formed using the second upper dielectric material (such as La₂O₃ or MgO) may be lower than that of the fourth NMOS transistor N_T4 including the fourth NMOS dielectric structure N_O4 formed using the first upper dielectric material (such as Al₂O₃).

Therefore, in the same manner as the PMOS transistors P_T, a layer formed using the second upper dielectric N_O2a may be referred to as the first shifter, while a layer formed using the first upper dielectric N_O3b may be referred as the second shifter. The first shifter may be formed using the second upper dielectric N_O2a increasing the threshold voltage of an NMOS transistor, while the second shifter may be formed using the first upper dielectric N_O3b decreasing the threshold voltage of the NMOS transistor.

In the second NMOS gate dielectric structure N_GO2 and the third NMOS gate dielectric structure N_GO3, the first upper dielectrics N_O2b and N_O3b may be referred to as the first shifter, while the second upper dielectrics N_O2a and N_O3a may be referred to as the second shifter. The second upper dielectrics N_O2a and N_O3a may act as the first shifter, and may include an Al-based dielectric, such as an Al oxide. In addition, the first upper dielectrics N_O2b and N_O3b may act as the second shifter, and may include a material forming a dipole layer, such as a La-based dielectric or a Mg-based dielectric.

The threshold voltage of the second NMOS transistor N_T2 may be different from that of the third NMOS transistor N_T3 by allowing a portion of the first upper dielectric N_O2b in the second NMOS gate dielectric structure N_GO2 to be different from the portion of the first upper dielectric N_O3b in the third NMOS gate dielectric structure N_GO3. For example, the first upper dielectric N_O2b in the second NMOS gate dielectric structure N_GO2 may have a thickness less than that of the first upper dielectric N_O3b in the third NMOS gate dielectric structure N_GO3.

The first to fourth PMOS transistors P_T1, P_T2, P_T3, and P_T4 and the first to fourth NMOS transistors N_T1, N_T2, N_T3, and N_T4 may be formed to have different threshold voltages by using the first upper dielectric acting as the first shifter and using the second upper dielectric acting as the second shifter. The first shifter (such as Al₂O₃) may allow the threshold voltage of a PMOS transistor to decrease and the threshold voltage of an NMOS transistor to increase, while the second shifter (such as a dipole layer) may allow the threshold voltage of the PMOS transistor to increase and the threshold voltage of the NMOS transistor to decrease.

According to example embodiments, the plurality of PMOS transistors P_T and the plurality of NMOS transistors N_T may control the threshold voltages by using the first shifter and the second shifter along with a common dielectric structure. Accordingly, gate dielectric structures that may be formed to be thin in a method of atomic layer disposition (ALD) may be formed to be structures, as illustrated above, thus controlling the threshold voltages of MOS transistors to be different from each other. Therefore, as a semiconductor device tends to be highly integrated, different gates may be formed stably in a limited space that tend to become gradually relatively small, such as a limited space between the first semiconductor layer P_S and the third semiconductor layer P_N. Therefore, process defects may be reduced, and efficiency may be improved.

According to an example embodiment, the plurality of PMOS transistors P_T having different threshold voltages and the plurality of NMOS transistors N_T having different threshold voltages, as illustrated above, may be provided. The plurality of PMOS transistors P_T and the plurality of NMOS transistors N_T may be configured to have various combinations, thus forming a semiconductor device.

According to an example embodiment, the semiconductor device may include at least two PMOS transistors having different threshold voltages among the plurality of PMOS transistors P_T and at least two NMOS transistors N_T having different threshold voltages among the plurality of NMOS transistors N_T.

According to an example embodiment, the semiconductor device may include the first PMOS transistor P_T1 and the second PMOS transistor P_T2.

According to an example embodiment, the semiconductor device may include the first PMOS transistor P_T1 and the second PMOS transistor P_T2 having different threshold voltages and the first NMOS transistor N_T1 and the second NMOS transistor N_T2 having different threshold voltages.

According to an example embodiment, the semiconductor device may include three PMOS transistors having different threshold voltages, including the first PMOS transistor P_T1, the fourth PMOS transistor P_T4, and one of the second PMOS transistor P_T2 and the third PMOS transistor P_T3, and may include three NMOS transistors having different threshold voltages, including the first NMOS transistor N_T1 the fourth NMOS transistor N_T4, and one of the second NMOS transistor N_T2 and the third NMOS transistor N_T3.

According to an example embodiment, the semiconductor device may include the first to fourth PMOS transistors P_T1, P_T2, P_T3, and P_T4 and the first to fourth NMOS transistors N_T1, N_T2, N_T3, and N_T4.

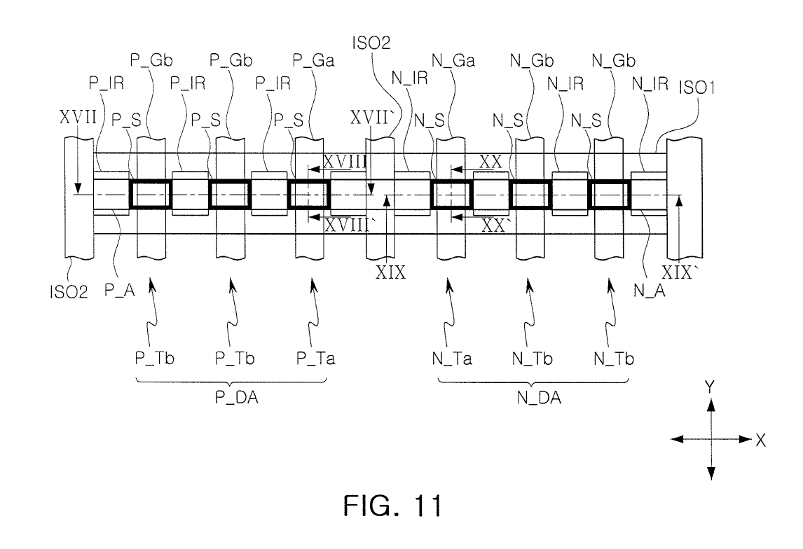

Examples of various combinations of the plurality of PMOS transistors P_T and the plurality of NMOS transistors N_T will now be described with reference to FIGS. 11 to 17b.

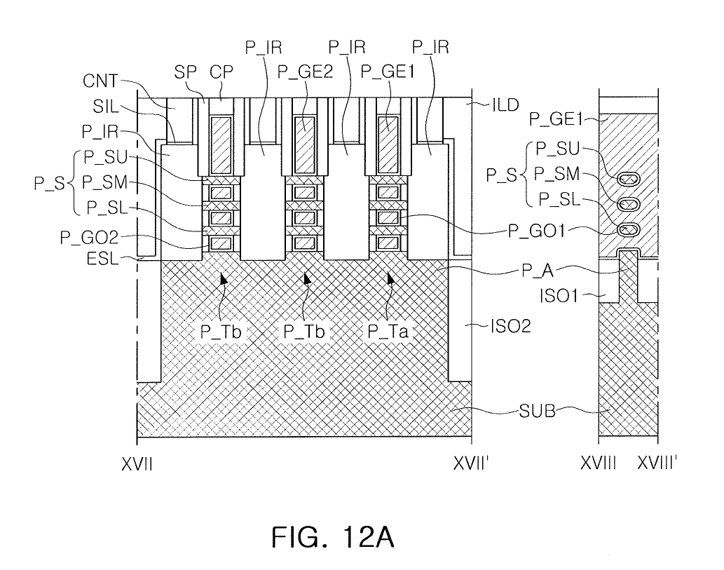

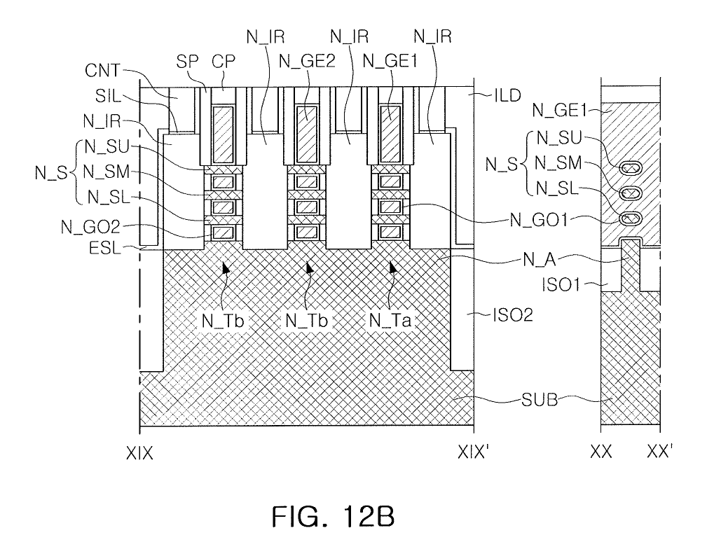

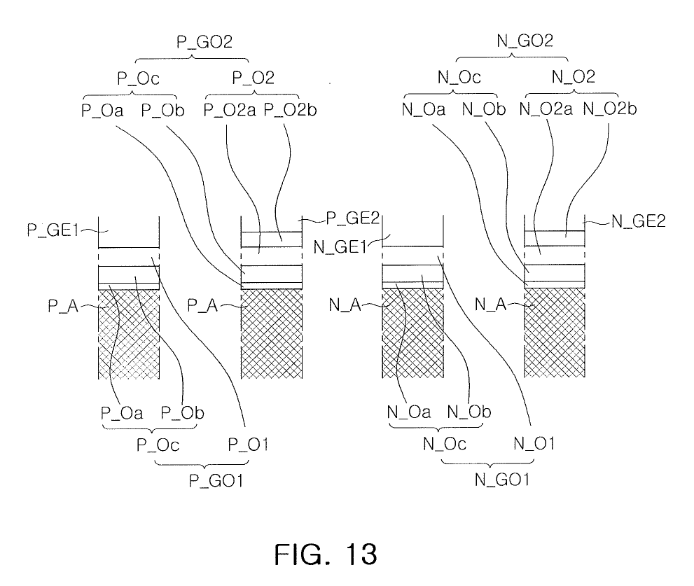

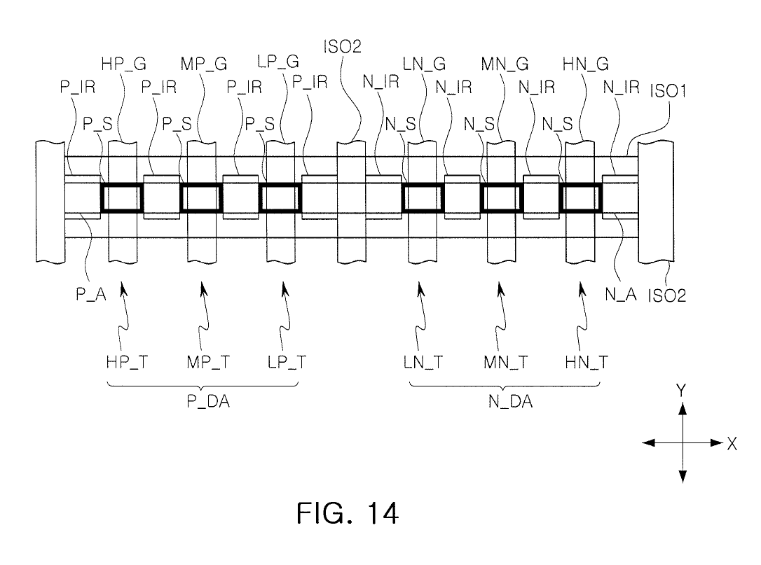

First, with reference to FIGS. 11 to 13, a description of a semiconductor device including PMOS transistors having different threshold voltages and NMOS transistors having different threshold voltages according to an example embodiment will be provided. In FIGS. 11 to 13, FIG. 11 is a plan view of a semiconductor device according to an example embodiment; FIG. 12A is a cross-sectional view taken along lines XVII-XVII′ and XVIII-XVIII′ of FIG. 11; FIG. 12B is a cross-sectional view taken along lines XIX-XIX′ and XX-XX′ of FIG. 11; and FIG. 13 is a partially enlarged view illustrating a gate dielectric structure of a semiconductor device according to an example embodiment.

With reference to FIGS. 11, 12A, 12B, and 13, a PMOS semiconductor pattern P_A may be disposed on a first device region P_DA of a semiconductor substrate SUB. An NMOS semiconductor pattern N_A having a conductivity type different from that of the PMOS semiconductor pattern P_A on a second device region N_DA of the semiconductor substrate SUB. The first device region P_DA may be provided as a PMOS device region, while the second device region N_DA may be provided as an NMOS device region.

The PMOS semiconductor pattern P_A may be referred to as a first semiconductor pattern, while the NMOS semiconductor pattern N_A may be referred to as a second semiconductor pattern. The PMOS semiconductor pattern P_A may have n-type conductivity, while the NMOS semiconductor pattern N_A may have p-type conductivity. The PMOS semiconductor pattern P_A and the NMOS semiconductor pattern N_A may have a line shape extended in a first direction X.

Isolation regions ISO1 and ISO2 limiting the PMOS semiconductor pattern P_A and the NMOS semiconductor pattern N_A may be disposed on the semiconductor substrate SUB. The isolation regions ISO1 and ISO2 may include first isolation regions ISO1 being parallel with the PMOS semiconductor pattern P_A and the NMOS semiconductor pattern N_A and having a line shape extended in the first direction X, and may include second isolation regions ISO2 limiting end portions of the PMOS semiconductor pattern P_A and the NMOS semiconductor pattern N_A and having a line shape extended in a second direction Y, perpendicular to the PMOS semiconductor pattern P_A and the NMOS semiconductor pattern N_A.

A plurality of PMOS source/drain regions P_IR spaced apart from each other may be disposed on the PMOS semiconductor pattern P_A of the first device region P_DA. A plurality of NMOS source/drain regions N_IR spaced apart from each other may be disposed on the NMOS semiconductor pattern N_A of the second device region N_DA. The plurality of PMOS source/drain regions P_IR may have conductivity different from that of the PMOS semiconductor pattern P_A, such as p-type conductivity. The plurality of NMOS source/drain regions N_IR may have conductivity different from that of the NMOS semiconductor pattern N_A, such as n-type conductivity.

A plurality of PMOS vertical structures P_S may be disposed between the plurality of PMOS source/drain regions P_IR. For example, each of the plurality of PMOS vertical structures P_S may be disposed between a pair of PMOS source/drain regions adjacent to each other among the plurality of PMOS source/drain regions P_IR. Each of the plurality of PMOS vertical structures P_S may be connected to and/or in contact with a pair of PMOS source/drain regions adjacent to each other. The plurality of PMOS vertical structures P_S may be disposed spaced apart from the PMOS semiconductor pattern P_A. Each of the plurality of PMOS vertical structures P_S may be disposed in sequence in a direction perpendicular to the PMOS semiconductor pattern P_A, and may include a first PMOS semiconductor layer P_SL, a second PMOS semiconductor layer P_SM, and a third PMOS semiconductor layer P_SU, spaced apart from each other. The first to third PMOS semiconductor layers P_SL, P_SM, and P_SU may have the same conductivity as that of the PMOS semiconductor pattern P_A, such as n-type conductivity.

A plurality of NMOS vertical structures N_S may be disposed among the plurality of NMOS source/drain regions N_IR. For example, each of the plurality of NMOS vertical structures N_S may be disposed between a pair of NMOS source/drain regions adjacent to each other among the plurality of NMOS source/drain regions N_IR. Each of the plurality of NMOS vertical structures N_S may be connected to and/or in contact with a pair of NMOS source/drain regions N_IR adjacent to each other. The plurality of NMOS vertical structures N_S may be disposed to be spaced from the NMOS semiconductor pattern N_A. Each of the plurality of NMOS vertical structures N_S may be disposed in sequence in a direction perpendicular to the NMOS semiconductor pattern N_A, and may include a first NMOS semiconductor layer N_SL, a second NMOS semiconductor layer N_SM, and a third NMOS semiconductor layer N_SU, spaced apart from each other. The first to third NMOS semiconductor layers N_SL, N_SM, and N_SU may have the same conductivity as that of the NMOS semiconductor pattern N_A, such as n-type conductivity.

The PMOS semiconductor pattern P_A and a plurality of PMOS gate structures P_Ga and P_Gb intersecting the plurality of PMOS vertical structures P_S may be disposed. The NMOS semiconductor pattern N_A and a plurality of NMOS gate structures N_Ga and N_Gb intersecting the plurality of NMOS vertical structures N_S may be disposed.

The plurality of PMOS gate structures P_Ga and P_Gb may correspond to the plurality of PMOS vertical structures P_S, respectively, and may intersect therewith. The plurality of NMOS gate structures N_Ga and N_Gb may correspond to the plurality of NMOS vertical structures N_S, respectively, and may intersect therewith.

The plurality of PMOS gate structures P_Ga and P_Gb may include a first PMOS gate structure P_Ga and a second PMOS gate structure P_Gb having different threshold voltages.

The first PMOS gate structure P_Ga may include the same material, and may have the same structure as those of the first PMOS gate structure P_G1, as illustrated with reference to FIGS. 1 and 2. For example, the first PMOS gate structure P_Ga may include the first PMOS gate dielectric structure P_GO1 and the first PMOS gate electrode structure P_GE1, as illustrated with reference to FIG. 2.

For example, the first PMOS gate dielectric structure P_GO1 may include the PMOS common dielectric structure P_Oc and the first PMOS dielectric structure P_O1 on the PMOS common dielectric structure P_Oc, as illustrated in FIG. 2.

The PMOS common dielectric structure P_Oc may include the PMOS interface dielectric P_Oa and the PMOS common high-k dielectric P_Ob, as illustrated in FIG. 2.

The first PMOS dielectric structure P_O1 may include the first upper dielectric, as illustrated in FIG. 2. The first PMOS dielectric structure P_O1 may include an Al-based dielectric, such as an Al oxide.

The second PMOS gate structure P_Gb may include a second PMOS gate dielectric structure P_GO2 and a second PMOS gate electrode structure P_GE2 on the second PMOS gate dielectric structure P_GO2. The second PMOS gate electrode structure P_GE2 may be the same as the second PMOS gate electrode structure P_GE2, as illustrated with reference to FIG. 3.

The second PMOS gate dielectric structure P_GO2 may include a PMOS common dielectric structure P_Oc and a second PMOS dielectric structure P_O2 on the PMOS common dielectric structure P_Oc. The PMOS common dielectric structure P_Oc of the second PMOS gate dielectric structure P_GO2 may be the same as the PMOS common dielectric structure P_Oc of the first PMOS gate dielectric structure P_GO1.

The second PMOS dielectric structure P_O2 may include a mixture of a first upper dielectric P_O2a and a second upper dielectric P_O2b.

In an example embodiment, the first upper dielectric P_O2a of the second PMOS dielectric structure P_O2 may include a material the same as that of the first PMOS dielectric structure P_O1.

In an example embodiment, the first upper dielectric P_O2a of the second PMOS dielectric structure P_O2 may include an Al-based dielectric, such as an Al oxide, the same as that of the first PMOS dielectric structure P_O1.

The second upper dielectric P_O2b of the second PMOS dielectric structure P_O2 may be formed to have a dipole layer. The dipole layer may include a La-based dielectric, such as a La oxide, or may include a Mg-based dielectric, such as a Mg oxide.

The plurality of NMOS gate structures N_Ga and N_Gb may include a first NMOS gate structure N_Ga and a second NMOS gate structure N_Gb having different threshold voltages.

The first NMOS gate structure N_Ga may include the same material, and may have the same structure as those of the first NMOS gate structure N_G1, as illustrated with reference to FIGS. 6 and 7. For example, the first NMOS gate structure N_Ga may include the first NMOS gate dielectric structure N_GO1 and the first NMOS gate electrode structure N_GE1, as illustrated with reference to FIG. 7.

The first NMOS gate dielectric structure N_GO1 may include the NMOS common dielectric structure N_Oc and the first NMOS dielectric structure N_O1 on the NMOS common dielectric structure N_Oc, as illustrated in FIG. 7.

The NMOS common dielectric structure N_Oc may include the NMOS interface dielectric N_Oa and the NMOS common high-k dielectric N_Ob. The NMOS interface dielectric N_Oa may include a Si oxide. The NMOS common high-k dielectric N_Ob may include an Hf-based dielectric, such as a Hf oxide.

The first NMOS dielectric structure N_O1 may include an upper dielectric. The first NMOS dielectric structure N_O1 may include a layer including the same material as that of the second upper dielectric of the second PMOS dielectric structure P_O2, such as a dipole layer. The dipole layer may include a La-based dielectric, such as a La oxide, or may include a Mg-based dielectric, such as a Mg oxide.

The second NMOS gate structure N_Gb may include a second NMOS gate dielectric structure N_O2 and a second NMOS gate electrode structure N_GE2 on the second NMOS gate dielectric structure N_O2. The second NMOS gate electrode structure N_GE2 may be the same as the second NMOS gate electrode structure N_GE2, as illustrated in FIG. 8.

The second NMOS gate dielectric structure N_GO2 may include an NMOS common dielectric structure N_Oc and a second NMOS dielectric structure N_O2 on the NMOS common dielectric structure N_Oc. The NMOS common dielectric structure N_Oc of the second NMOS gate dielectric structure N_GO2 may be the same as the NMOS common dielectric structure N_Oc of the first NMOS gate dielectric structure N_GO1.

The second NMOS dielectric structure N_O2 may include a mixture of a second upper dielectric N_O2a and a first upper dielectric N_O2b. The second upper dielectric N_O2a may include an Al-based high-k dielectric, such as an Al oxide, while the first upper dielectric N_O2b may be formed to have a dipole layer. The dipole layer may include a La-based dielectric, such as a La oxide, or may include a Mg-based dielectric, such as a Mg oxide.

In an example embodiment, the second upper dielectric N_O2a may be disposed between the NMOS common dielectric N_Oc and the second NMOS gate electrode structure N_GE2 in the second NMOS dielectric structure N_O2. In addition, the first upper dielectric P_O2a may be disposed between the PMOS common dielectric P_Oc and the second PMOS upper dielectric P_O2b in the second PMOS dielectric structure P_O2.

The first PMOS gate structure P_Ga formed on the PMOS semiconductor pattern P_A, the PMOS vertical structure P_S overlapping the first PMOS gate structure P_Ga, and a pair of PMOS source/drain regions P_IR disposed on both sides of the first PMOS gate structure P_Ga may configure a first PMOS transistor P_Ta.

The second PMOS gate structure P_Gb formed on the PMOS semiconductor pattern P_A, the PMOS vertical structure P_S overlapping the second PMOS gate structure P_Gb, and a pair of PMOS source/drain regions P_IR disposed on both sides of the second PMOS gate structure P_Gb may configure a second PMOS transistor P_Tb.

In an example embodiment, the first PMOS gate structure P_Ga and the second PMOS gate structure P_Gb of the first PMOS transistor P_Ta and the second PMOS transistor P_Tb may be disposed to be adjacent to each other. The first PMOS transistor P_Ta and the second PMOS transistor P_Tb may share PMOS source/drain regions P_IR disposed between the first PMOS gate structure P_Ga and the second PMOS gate structure P_Gb disposed adjacently to each other.

The first NMOS gate structure N_Ga formed on the NMOS semiconductor pattern N_A, the NMOS vertical structure N_S overlapping the first NMOS gate structure N_Ga, and a pair of NMOS source/drain regions N_IR disposed on both sides of the first NMOS gate structure N_Ga may configure a first NMOS transistor N_Ta.

The second NMOS gate structure N_Gb formed on the NMOS semiconductor pattern N_A, the NMOS vertical structure N_S overlapping the second NMOS gate structure N_Gb, and a pair of NMOS source/drain regions N_IR disposed on both sides of the second NMOS gate structure N_Gb may configure a second NMOS transistor N_Tb.

In an example embodiment, the first NMOS gate structure N_Ga and the second NMOS gate structure N_Gb of the first NMOS transistor N_Ta and the second NMOS transistor N_Tb may be disposed to be adjacent to each other. The first NMOS transistor N_Ta and the second NMOS transistor N_Tb may share NMOS source/drain regions N_IR disposed between the first NMOS gate structure N_Ga and the second NMOS gate structure N_Gb disposed adjacently to each other.

Protective insulating layers PI may be disposed between the PMOS semiconductor pattern P_A and the first PMOS semiconductor layer P_SL, may be disposed between the first PMOS semiconductor layer P_SL and the second PMOS semiconductor layer P_SM, and may be disposed between the second PMOS semiconductor layer P_SM and the third PMOS semiconductor layer P_SU. The protective insulating layer PI may be disposed between the first PMOS gate P_Ga and the PMOS source/drain regions P_IR, and may be disposed between the second PMOS gate P_Gb and the PMOS source/drain regions P_IR.

Gate capping patterns CP having electrical insulating properties may be disposed on the first PMOS gate electrode structure P_GE1, the second PMOS gate electrode structure P_GE2, the first NMOS gate electrode structure N_GE1, and the second NMOS gate electrode structure N_GE2. Gate spacers SP having electrical insulating properties may be disposed on a side surface of the gate capping patterns CP. The gate spacers SP may be disposed on side surfaces of the first PMOS gate electrode structure P_GE1, the second PMOS gate electrode structure P_GE2, the first NMOS gate electrode structure N_GE1, and the second NMOS gate electrode structure N_GE2, disposed on the PMOS vertical structure P_S and the NMOS vertical structure N_S. A metallic silicide layer SIL and a conductive contact structure CNT may be disposed on the PMOS source/drain regions P_IR and the NMOS source/drain regions N_IR in sequence. An insulating layer ID may be disposed on the second isolation region ISO2. An insulating liner ESL may be disposed between the insulating layer ID and the second isolation region ISO2, and may be disposed among the insulating layer ID, the PMOS source/drain regions P_IR, and the NMOS source/drain regions N_IR.

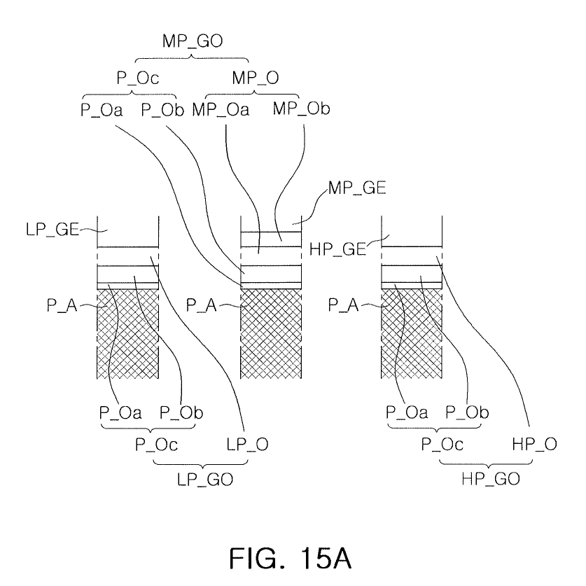

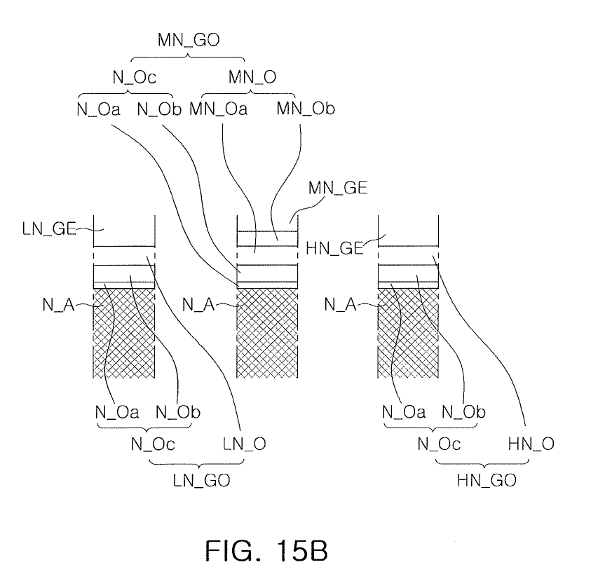

Next, with reference to FIGS. 14, 15A, and 15B, a description of a semiconductor device including PMOS transistors having different threshold voltages and NMOS transistors having different threshold voltages according to an example embodiment will be provided. In FIGS. 14, 15A, and 15B, FIG. 14 is a plan view of the semiconductor device according to an example embodiment; FIG. 15A is partially enlarged views illustrating gate dielectric structures of PMOS transistors; and FIG. 15B is partially enlarged views illustrating gate dielectric structures of NMOS transistors.

In FIGS. 14, 15A, and 15B, terms “high”, “low”, and “mixed” are used to distinguish components in order to facilitate a description of an example embodiment, but terms “high”, “low”, and “mixed” may be substituted with “first”, “second”, and “third”, or may be substituted with other terms.

With reference to FIGS. 14, 15A, and 15B, the PMOS semiconductor pattern P_A, the NMOS semiconductor pattern N_A the isolation regions ISO1 and ISO2, the plurality of PMOS source/drain regions P_IR, the plurality of NMOS source/drain regions N_IR, the plurality of PMOS vertical structures P_S, and the plurality of NMOS vertical structures N_S, as illustrated in FIGS. 11 to 13, may be disposed on a semiconductor substrate SUB.

PMOS gate structures intersecting the plurality of PMOS vertical structures P_S may be disposed on the PMOS semiconductor pattern P_A. NMOS gate structures intersecting the plurality of NMOS vertical structures N_S may be disposed on the NMOS semiconductor pattern N_A.

The PMOS gate structures may include a low PMOS gate structure LP_G, a mixed PMOS gate structure MP_G, and a high PMOS gate structure HP_G. The NMOS gate structures may include a low NMOS gate structure LN_G, a mixed NMOS gate structure MN_G, and a high NMOS gate structure HN_G.

The low PMOS gate structure LP_G may include a low PMOS gate dielectric structure LP_GO and a low PMOS gate electrode structure LP_GE on the low PMOS gate dielectric structure LP_GO. The mixed PMOS gate structure MP_G may include a mixed PMOS gate dielectric structure MP_GO and a mixed PMOS gate electrode structure MP_GE on the mixed PMOS gate dielectric structure MP_GO. The high PMOS gate structure HP_G may include a high PMOS gate dielectric structure HP_GO and a high PMOS gate electrode structure HP_GE on the high PMOS gate dielectric structure HP_GO.

The low PMOS gate electrode structure LP_GE may be the same as the first PMOS gate electrode structure P_GE1 illustrated in FIG. 2; the mixed PMOS gate electrode structure MP_GE may be the same as the second PMOS gate electrode structure P_GE2 illustrated in FIG. 3; and the high PMOS gate electrode structure HP_GE may be the same as the fourth PMOS gate electrode structure P_GE4 illustrated in FIG. 5.

A low NMOS gate electrode structure LN_GE may be the same as the first NMOS gate electrode structure N_GE1 illustrated in FIG. 7; a mixed NMOS gate electrode structure MN_GE may be the same as the second NMOS gate electrode structure N_GE2 illustrated in FIG. 8; and a high NMOS gate electrode structure HN_GE may be the same as a fourth NMOS gate electrode structure N_GE4 illustrated in FIG. 10.

The low PMOS gate dielectric structure LP_GO may include a PMOS common dielectric structure P_Oc and a low PMOS dielectric structure LP_O, respectively corresponding to the PMOS common dielectric structure P_Oc and the first PMOS dielectric structure P_O1, illustrated in FIG. 2.

The mixed PMOS gate dielectric structure MP_GO may include a PMOS common dielectric structure P_Oc and a mixed PMOS dielectric structure MP_O, respectively corresponding to the PMOS common dielectric structure P_Oc and the second PMOS dielectric structure P_O2, illustrated in FIG. 3. The mixed PMOS dielectric structure MP_O may include a first upper dielectric MP_Oa and a second upper dielectric MP_Ob, respectively corresponding to the first upper dielectric P_O2a and the second upper dielectric P_O2b, illustrated in FIG. 3.

A high PMOS gate dielectric structure HP_GO may include a PMOS common dielectric structure P_Oc and a high PMOS dielectric structure HP_O, respectively corresponding to the PMOS common dielectric structure P_Oc and the fourth PMOS dielectric structure P_O4, illustrated in FIG. 5.

A low NMOS gate dielectric structure LN_GO may include an NMOS common dielectric structure N_Oc and a low NMOS dielectric structure LN_O, respectively corresponding to the NMOS common dielectric structure N_Oc and the first NMOS dielectric structure N_O1, illustrated in FIG. 7.

A mixed NMOS gate dielectric structure MN_GO may include an NMOS common dielectric structure N_Oc and a mixed NMOS dielectric structure MN_O, respectively corresponding to the NMOS common dielectric structure N_Oc and the second NMOS dielectric structure N_O2, illustrated in FIG. 8. The mixed NMOS dielectric structure MN_O may include a first upper dielectric MN_Oa and the second upper dielectric MN_Ob, respectively corresponding to the second upper dielectric N_O2a and the second upper dielectric P_O2b, illustrated in FIG. 8.

A high NMOS dielectric structure HN_GO may include an NMOS common dielectric structure N_Oc and a high NMOS dielectric structure HN_O, respectively corresponding to the NMOS common dielectric structure N_Oc and the fourth NMOS dielectric structure N_O4, illustrated in FIG. 10.

The low PMOS gate structure LP_G formed on the PMOS semiconductor pattern P_A, the PMOS vertical structure P_S overlapping the low PMOS gate structure LP_G, and a pair of PMOS source/drain regions P_IR disposed on both sides of the low PMOS gate structure LP_G may configure a low PMOS transistor LP T.

The mixed PMOS gate structure MP_G formed on the PMOS semiconductor pattern P_A, the PMOS vertical structure P_S overlapping the mixed PMOS gate structure MP_G, and a pair of PMOS source/drain regions P_IR disposed on both sides of the mixed PMOS gate structure MP_G may configure a mixed PMOS transistor MP_T.

The high PMOS gate structure HP_G formed on the PMOS semiconductor pattern P_A, the PMOS vertical structure P_S overlapping the high PMOS gate structure HP_G, and a pair of PMOS source/drain regions P_IR disposed on both sides of the high PMOS gate structure HP_G may configure a high PMOS transistor HP_T.

The low NMOS gate structure LN_G formed on the NMOS semiconductor pattern N_A, the NMOS vertical structure N_S overlapping the low NMOS gate structure LN_G, and a pair of NMOS source/drain regions N_IR disposed on both sides of the low NMOS gate structure LN_G may configure a low NMOS transistor LN T.

The mixed NMOS gate structure MN_G formed on the NMOS semiconductor pattern N_A, the NMOS vertical structure N_S overlapping the mixed NMOS gate structure MN_G, and a pair of NMOS source/drain regions N_IR disposed on both sides of the mixed NMOS gate structure MN_G may configure a mixed NMOS transistor MN T.

The high NMOS gate structure HN_G formed on the NMOS semiconductor pattern N_A, the NMOS vertical structure N_S overlapping the high NMOS gate structure HN_G, and a pair of NMOS source/drain regions N_IR disposed on both sides of the high NMOS gate structure HN_G may configure a high NMOS transistor HN_T.

In an example embodiment, the low PMOS transistor LP_T may correspond to the first PMOS transistor P_T1 illustrated in FIG. 2; the mixed PMOS transistor MP_T may correspond to the second PMOS transistor P_T2 illustrated in FIG. 3 or the third PMOS transistor P_T3 illustrated in FIG. 4; and the high PMOS transistor HP_T may correspond to the fourth PMOS transistor P_T4 illustrated in FIG. 5.

In an example embodiment, the low NMOS transistor LN_T may correspond to the first NMOS transistor N_T1 illustrated in FIG. 7; the mixed NMOS transistor MN_T may correspond to the second NMOS transistor N_T2 illustrated in FIG. 8 or the third NMOS transistor N_T3 illustrated in FIG. 9; and the high NMOS transistor I-IN T may correspond to the fourth NMOS transistor N_T4 illustrated in FIG. 10.

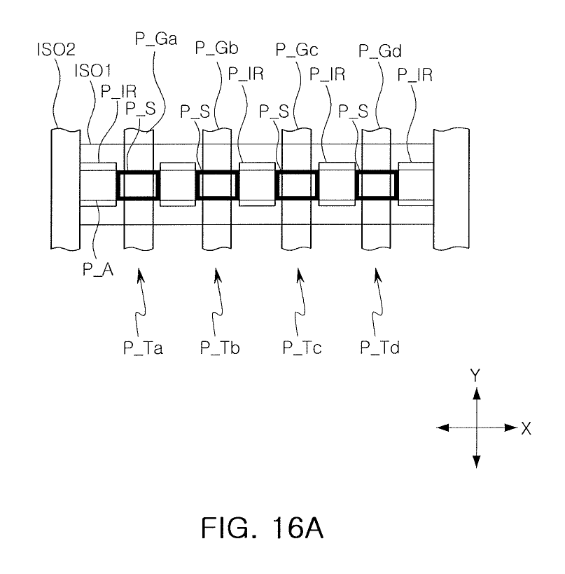

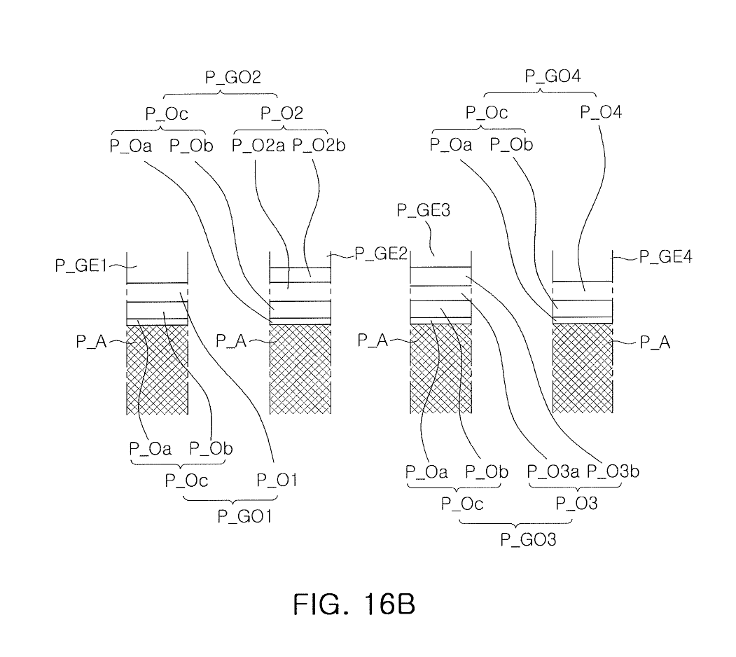

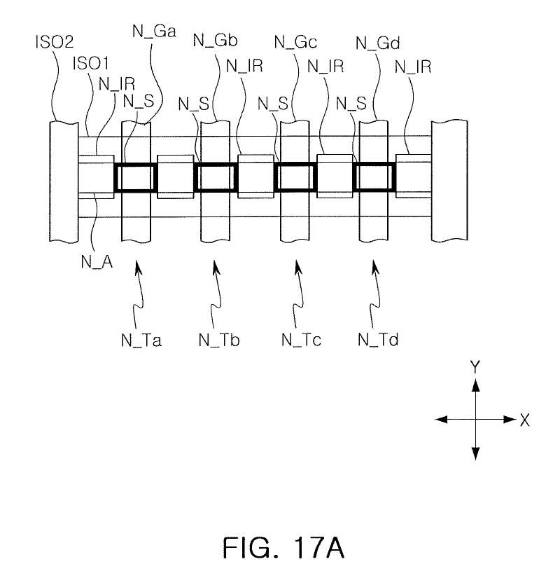

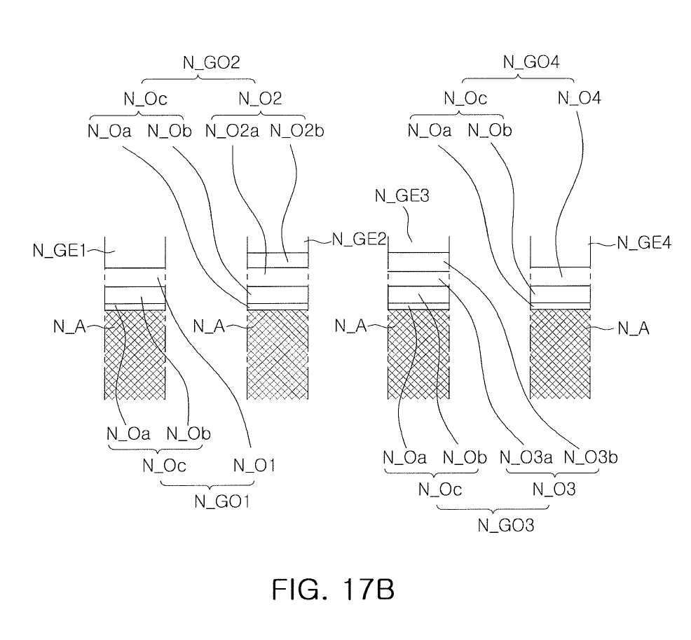

Next, with reference to FIGS. 16A, 16B, 17A, and 17B, a description of a semiconductor device including PMOS transistors having different threshold voltages and NMOS transistors having different threshold voltages according to an example embodiment. In FIGS. 16A, 16B, 17A, and 17B, FIG. 16A is a plan view of PMOS transistors in a semiconductor device according to an example embodiment; FIG. 16B is partially enlarged views illustrating gate dielectric structures of PMOS transistors; FIG. 17A is a plan view of NMOS transistors in a semiconductor device according to an example embodiment; and FIG. 17B is partially enlarged views illustrating gate dielectric structures of NMOS transistors.

With reference to FIGS. 16A, 16B, 17A, and 17B, the PMOS semiconductor pattern P_A, the NMOS semiconductor pattern N_A, the isolation regions ISO1 and ISO2, the plurality of PMOS source/drain regions P_IR, the plurality of NMOS source/drain regions N_IR, the plurality of PMOS vertical structures P_S, and the plurality of NMOS vertical structures N_S, as illustrated in FIGS. 11 to 13, may be disposed on a semiconductor substrate SUB.

First to fourth PMOS transistors P_Ta, P_Tb, P_Tc, and P_Td having different threshold voltages may be disposed on the semiconductor substrate SUB. First to fourth NMOS transistors N_Ta, N_Tb, N_Tc, and N_Td having different threshold voltages may be disposed on the semiconductor substrate SUB.

The first to fourth PMOS transistors P_Ta, P_Tb, P_Tc, and P_Td may, respectively, correspond to the first to fourth PMOS transistors P_T1, P_T2, P_T3, and P_T4 illustrated with reference to FIGS. 1 to 5. The first to fourth NMOS transistors N_Ta, N_Tb, N_Tc, and N_Td may, respectively, correspond to the first to fourth NMOS transistors N_T1, N_T2, N_T3, and N_T4 illustrated with reference to FIGS. 6 to 10. For example, the first to fourth PMOS gate structures P_Ga. P_Gb, P_Gc, and P_Gd of the first to fourth PMOS transistors P_Ta, P_Tb, P_Tc, and P_Td may, respectively, correspond to the first to fourth PMOS gate structures P_G1, P_G2, P_G3, and P_G4 illustrated with reference to FIGS. 1 to 5. First to fourth NMOS gate structures N_Ga, N_Gb, N_Gc, and N_Gd of the first to fourth NMOS transistors N_Ta, N_Tb, N_Tc, and N_Td may, respectively, correspond to the first to fourth NMOS gate structures N_G1, N_G2, N_G3, and N_G4 illustrated with reference to FIGS. 6 to 10.

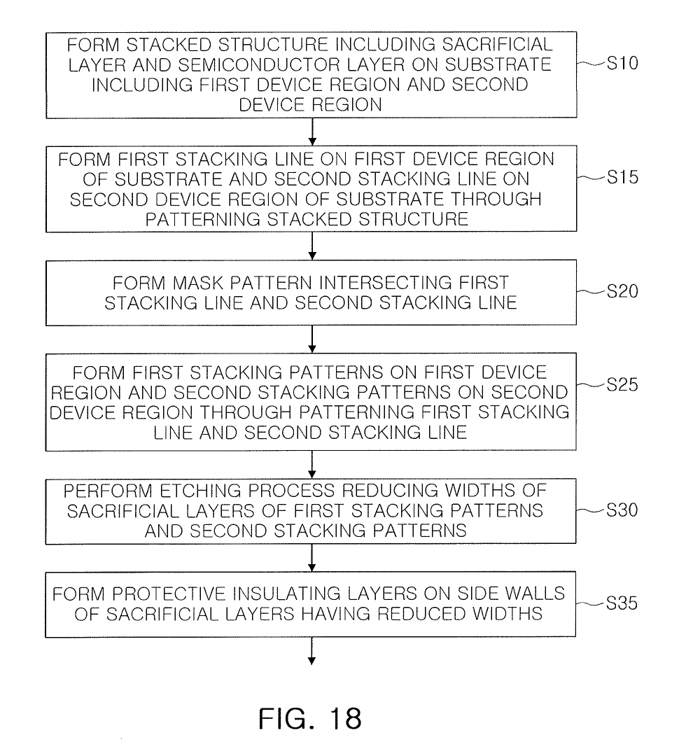

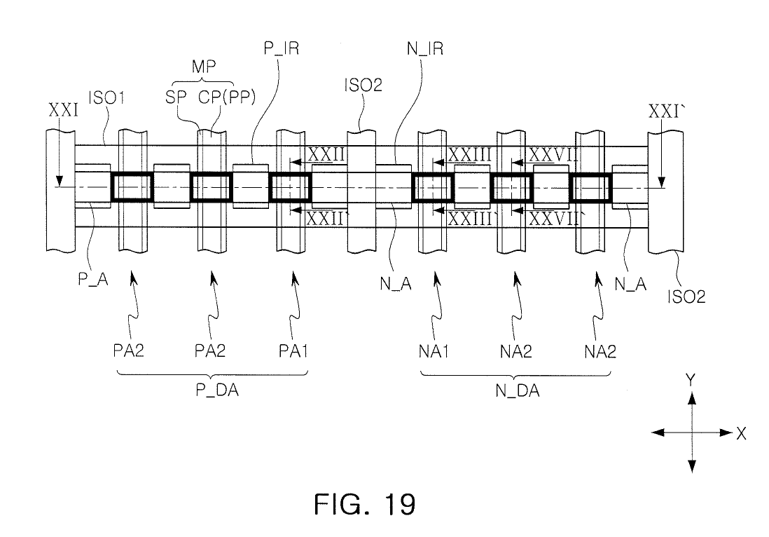

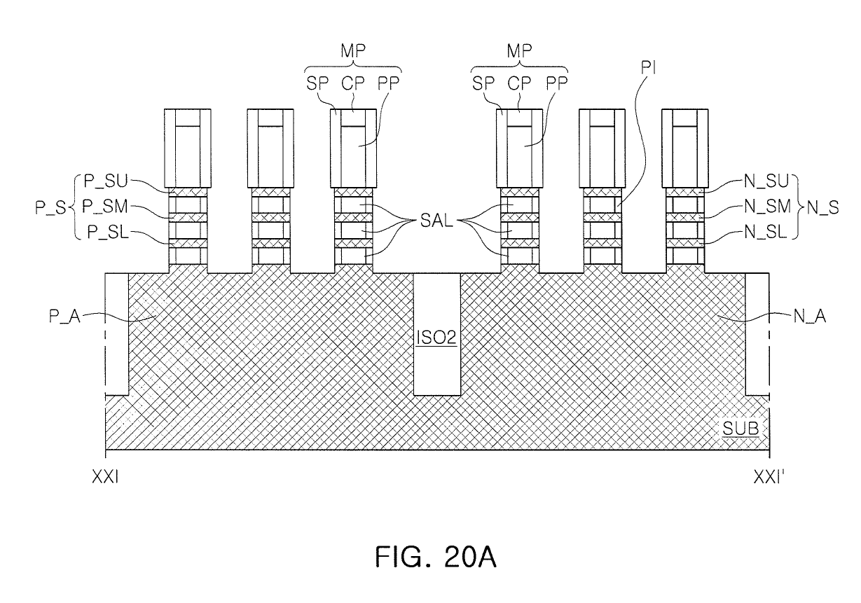

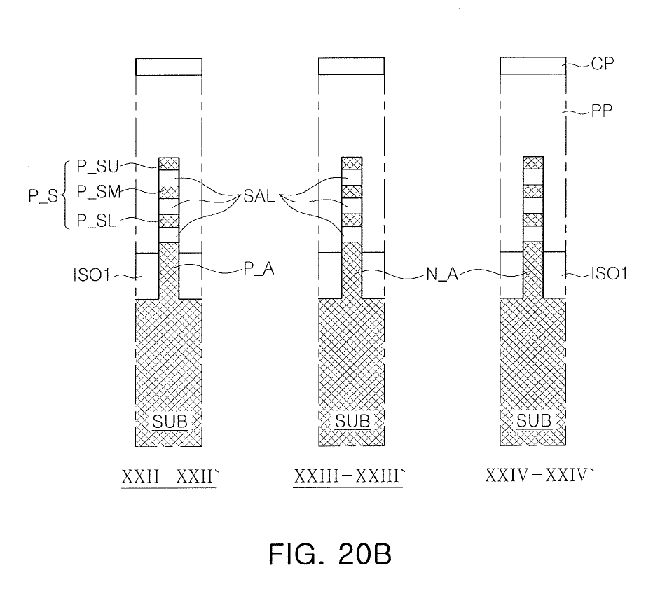

Next, a description of a method of forming a semiconductor device according to an example embodiment will be provided. A description of a method of the semiconductor device according to an example embodiment illustrated in FIGS. 11 to 13 will be provided with reference to FIGS. 18 to 37B. In FIGS. 18 to 36B, FIGS. 18, 21, 25, 30, and 34 are process flow charts of a method of forming the semiconductor device according to an example embodiment; FIG. 19 is a plan view of a method of forming the semiconductor device according to an example embodiment; FIGS. 20A, 22A, 23A, 24A, 26A, 27A, 28A, 29A, 31A, 32A, 33A, 35A, 36A, and 37A are cross-sectional views taken along line XXI-XXI′ of FIG. 19; FIGS. 20B, 22B, 23B, 24B, 26B, 27B, 28B, 29B, 31B, 32B, 33B, 35B, 36B, and 37B are cross-sectional views taken along lines XXII-XXII′, XXIII-XXIII′, and XXIV-XXIV′ of FIG. 19. Line XXI-XXI′ in FIG. 19 may be the same as a line connecting line XVII-XVII′ with line XIX-XIX′ in FIG. 11.

With reference to FIGS. 18, 19, 20A, and 20B, a stacked structure including a sacrificial layer and a semiconductor layer may be formed on a substrate SUB including a first device region P_DA and a second device region N_DA in S10. The sacrificial layer and the semiconductor layer may be stacked alternately and repeatedly. For example, the stacked structure may include a first sacrificial layer, a first semiconductor layer, a second sacrificial layer, a second semiconductor layer, a third sacrificial layer, and a third semiconductor layer, disposed on the substrate SUB in sequence. The substrate SUB may be provided as a semiconductor substrate. The first to third sacrificial layers may include a material having a selective etching rate with respect to the first to third semiconductor layers. For example, the first to third sacrificial layers may include a material, such as silicon-germanium (Site), or the like, while the first to third semiconductor layers may include a material, such as Si, or the like.

Through patterning the stacked structure, a first stacking line on the first device region P_DA of the substrate SUB and a second stacking line on the second device region N_DA of the substrate SUB may be formed in S15.

In an example embodiment, the first stacking line may be connected to the second stacking line.

In an example embodiment, first isolation regions ISO1 may be formed within the substrate SUB. The first isolation regions ISO1 may be parallel with the first stacking line and the second stacking line from a top view.

In an example embodiment, second isolation regions ISO2 may be formed within the substrate SUB. The second isolation regions ISO2 may be perpendicular to the first stacking line and the second stacking line.

In the case of the first isolation regions ISO1 and the second isolation regions ISO2, a PMOS semiconductor pattern P_A may be limited in the substrate SUB of the first device region P_DA, while an NMOS semiconductor pattern N_A may be limited in the substrate SUB of the second device region N_DA. The PMOS semiconductor pattern P_A and the NMOS semiconductor pattern N_A may be formed to have a line shape.

A mask pattern MP intersecting the first stacking line and the second stacking line may be formed in S20. Each of the mask patterns MP may include a mask line PP, a capping pattern CP on the mask line, and a spacer SP on side surfaces of the mask line PP and the capping pattern CP. The mask line PP may include polysilicon, while the capping pattern CP and the spacer SP may include a Si nitride.

First stacking patterns on the first device region P_DA and second stacking patterns on the second device region N_DA may be formed through patterning the first stacking line and the second stacking line using the mask patterns MP as an etching mask in S25.

The first stacking patterns may include a PMOS vertical structure P_S, while the second stacking patterns may include an NMOS vertical structure N_S. The PMOS vertical structure P_S may include a first PMOS semiconductor layer P_SL, a second PMOS semiconductor layer P_SM, and a third PMOS semiconductor layer P_SU, disposed spaced apart from each other in a vertical direction. The NMOS vertical structure N_S may include a first NMOS semiconductor layer N_SL, a second NMOS semiconductor layer N_SM, and a third NMOS semiconductor layer N_SU, disposed spaced apart from each other in a vertical direction.

The PMOS stacking patterns and the NMOS stacking patterns may include sacrificial layers SAL. The sacrificial layers SAL may include patterns disposed between the PMOS vertical structure P_S and the PMOS semiconductor pattern P_A, and disposed between the NMOS vertical structure N_S and the NMOS semiconductor pattern N_A, may include patterns disposed among semiconductor layers P_SL, P_SM, and P_SU of the PMOS vertical structure P_S, and may include patterns disposed among semiconductor layers N_SL, N_SM, and N_SU of the NMOS vertical structure N_S.

An etching process reducing widths of the sacrificial layers SAL may be performed in S30. Protective insulating layers PI may be formed on side walls of the sacrificial layers SAL having reduced widths.

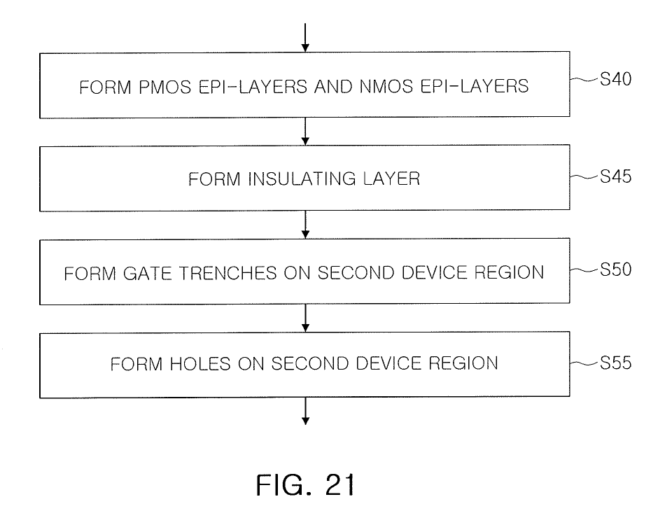

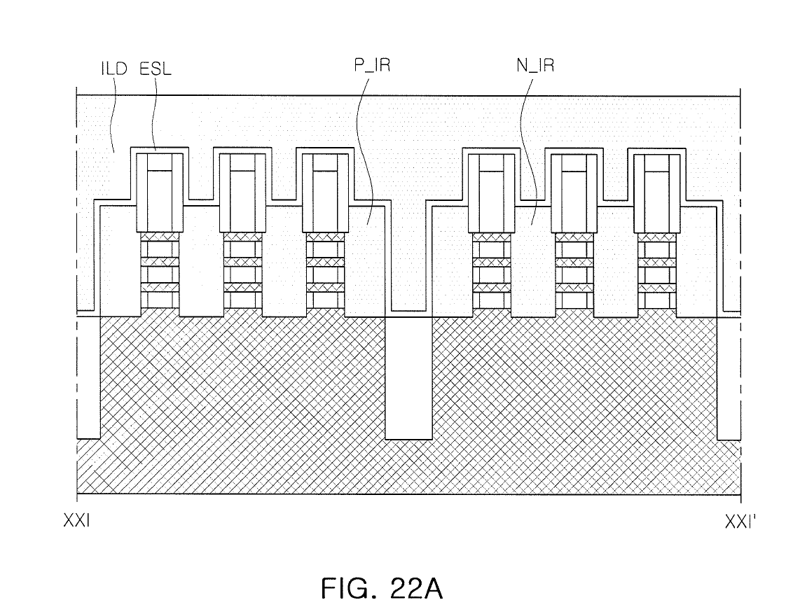

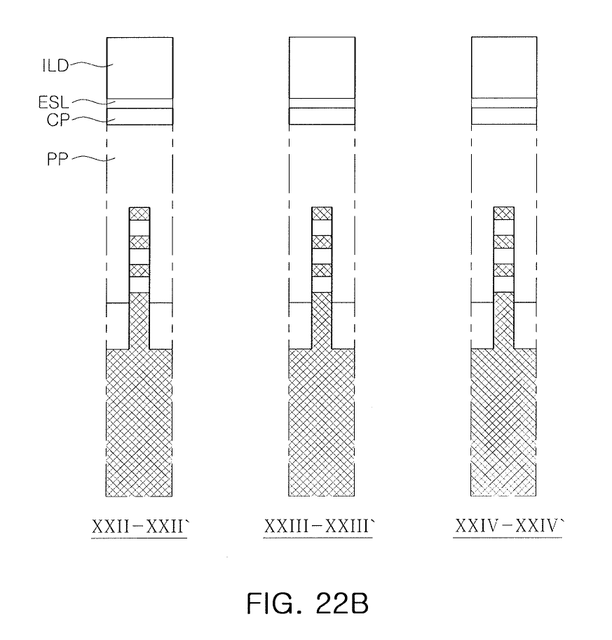

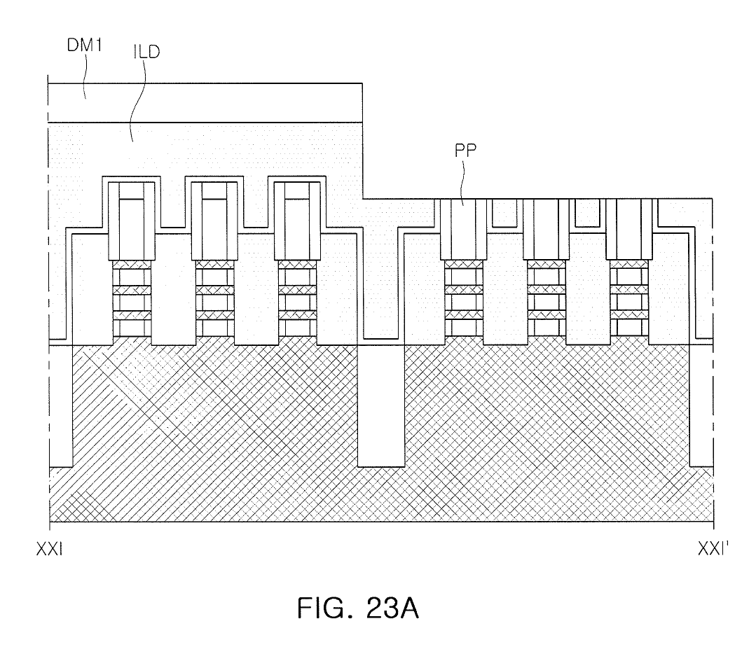

With reference to FIGS. 21, 22A, and 22B, PMOS epi-layers and NMOS epi-layers may be formed in S40. The PMOS epi-layers may be formed of a semiconductor material using a method of selective epitaxial growth. The PMOS epi-layers may be PMOS source/drain regions P_IR. The PMOS source/drain regions P_IR may be formed on the PMOS semiconductor pattern P_A, and may be connected to the PMOS vertical structure P_S. The NMOS epi-layers may be formed of the semiconductor material using the method of selective epitaxial growth. The NMOS epi-layers may be NMOS source/drain regions N_IR. The NMOS source/drain regions N_IR may be formed on the NMOS semiconductor pattern N_A, and may be connected to the NMOS vertical structure N_S. An insulating liner ESL may be disposed on a substrate including the PMOS source/drain regions P_IR and the NMOS source/drain regions N_IR. The insulating liner ESL may include an insulating material, such as a Si nitride. An insulating layer ILD may be formed on the insulating liner ESL in S45.

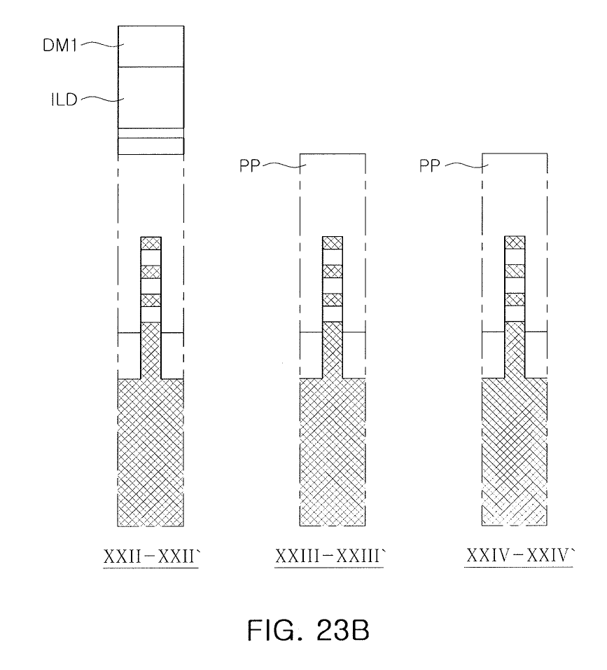

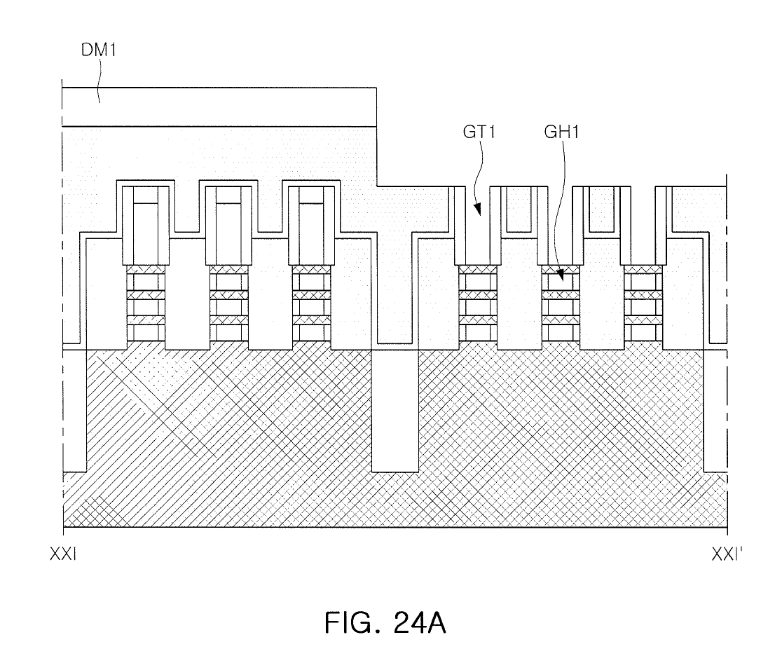

With reference to FIGS. 23A and 23B, a first device protection mask DM1 may be formed on the insulating layer ILD on the first device region P_DA. The insulating layer ILD and the capping patterns CP may be etched using the first device protection mask DM1 as an etching mask to allow the mask lines PP of the second device region N_DA to be exposed.

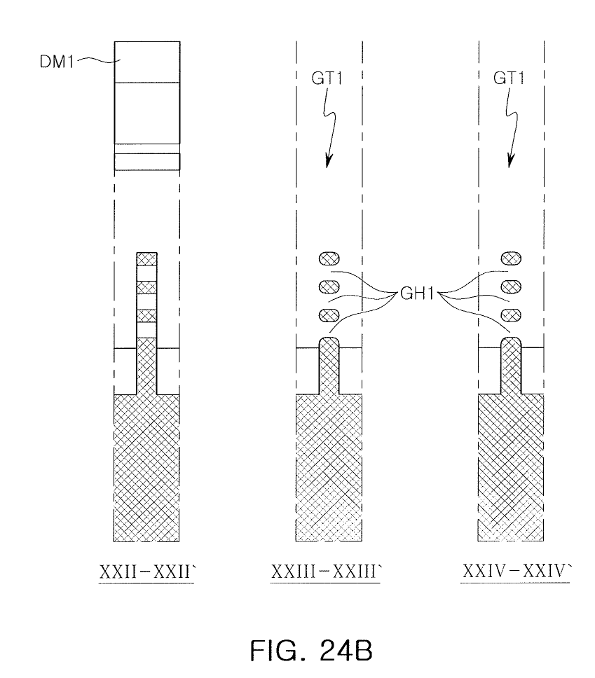

With reference to FIGS. 21, 24A, and 24B, gate trenches GT1 may be formed on the second device region N_DA in S50. The gate trenches GT1 may be formed in such a manner that the exposed mask lines (see PP in FIGS. 23A and 23B) are removed selectively. When the gate trenches GT1 are formed in the second device region N_DA, the sacrificial layers SAL may be exposed. Holes GH1 may be formed on the second device region in S55. The holes GH1 may be formed in such a manner that the sacrificial patterns SAL in the second device region N_DA, exposed by the gate trenches GT1, are removed.

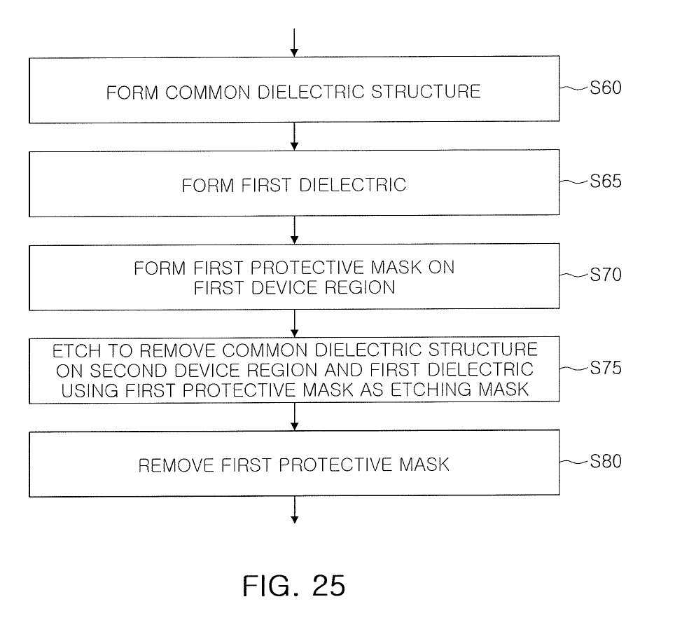

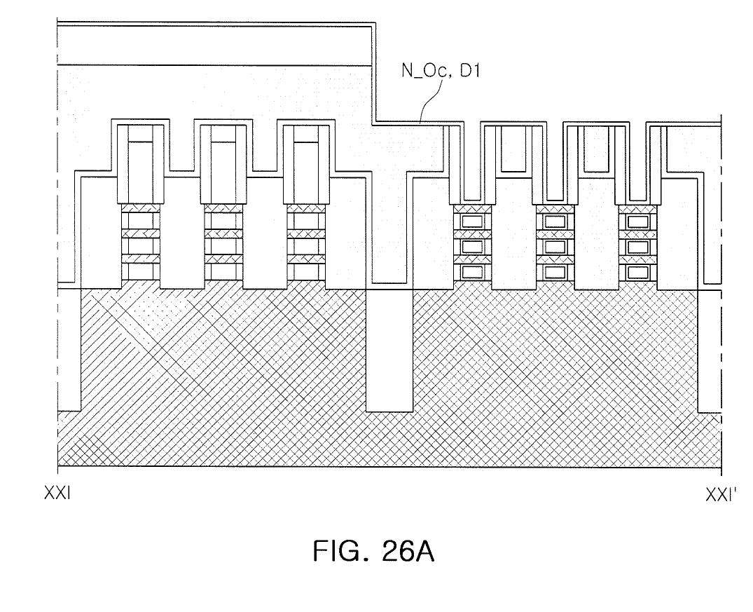

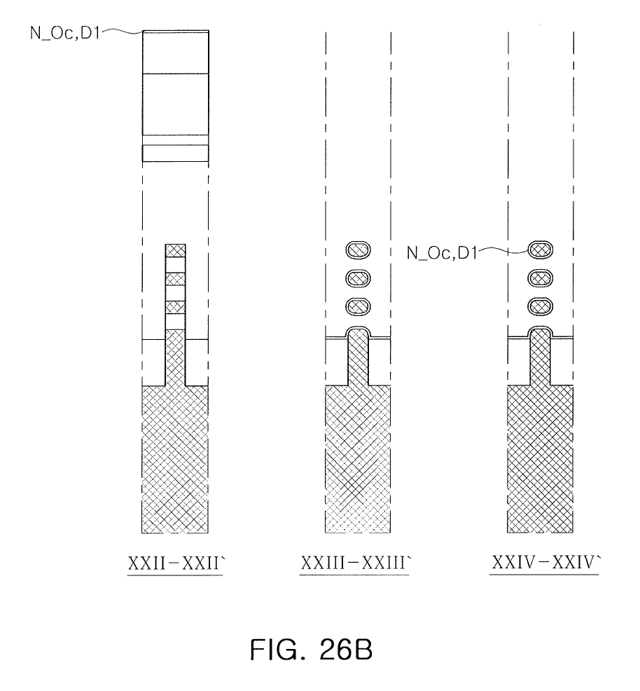

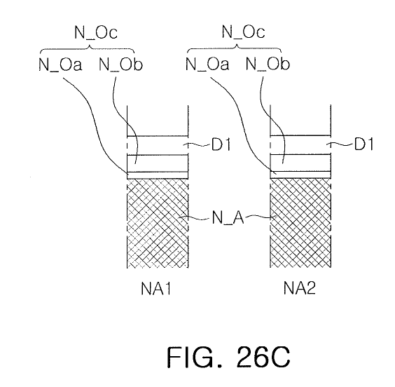

With reference to FIGS. 25, 26A, 26B, and 26C, a common dielectric structure N_Oc may be formed in S60. The common dielectric structure N_Oc may be formed conformally on a substrate including the gate trenches GT1 and the holes GH1. A first dielectric D1 may be formed on the common dielectric structure N_Oc in S65. The common dielectric structure N_Oc may include an interface dielectric N_Oa and a common high-k dielectric N_Ob on the interface dielectric N_Oa. The interface dielectric N_Oa may include a Si oxide. The common high-k dielectric N_Ob may include an Hf-based dielectric, such as a Hf oxide. The first dielectric D1 may be formed to have a dipole layer. The dipole layer may be provided as a La-based dielectric, such as a La oxide, or may be provided as a Mg-based dielectric, such as a Mg oxide.

In an example embodiment, the first dielectric D1 may correspond to the first NMOS dielectric structure (see N_O1 in FIG. 7) illustrated in FIG. 7.

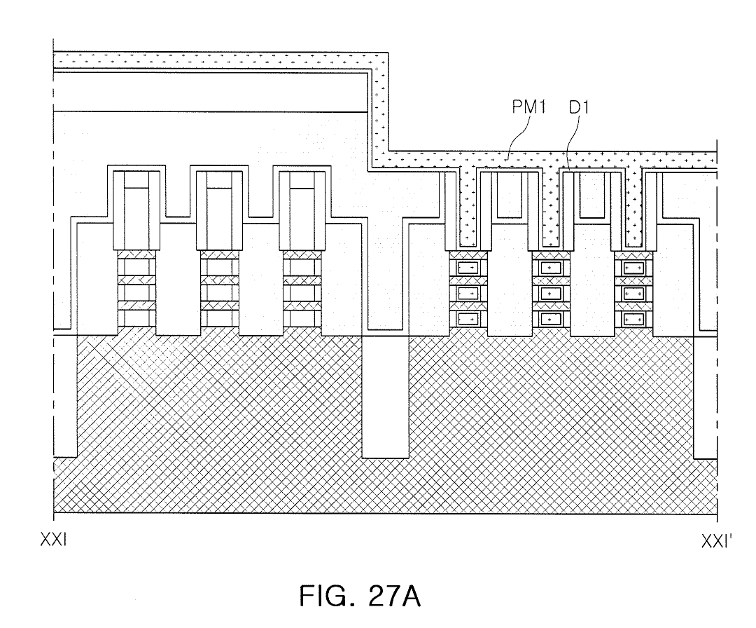

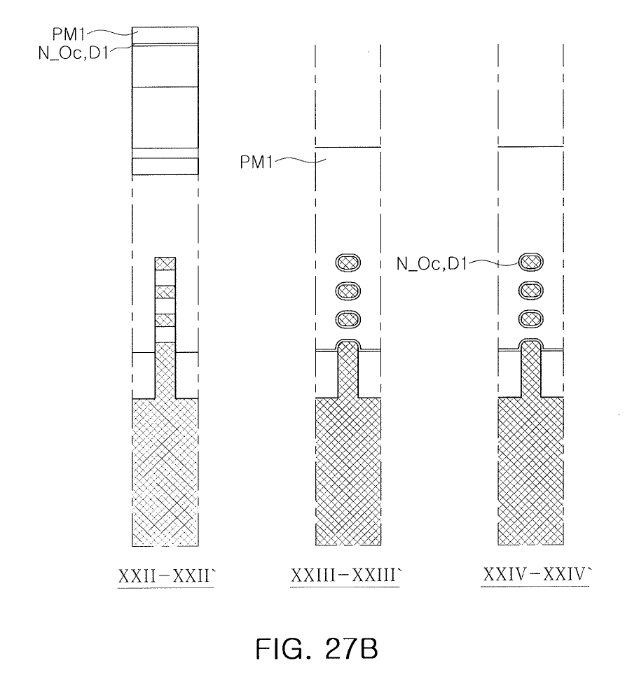

With reference to FIGS. 27A and 27B, a first protective layer PM1 may be formed on the first dielectric D1 in S70. The first protective layer PM1 may include a material having a selective etching rate with respect to the first dielectric D1. For example, the first protective layer PM1 may be formed using a metallic nitride, such as a titanium (Ti) nitride.

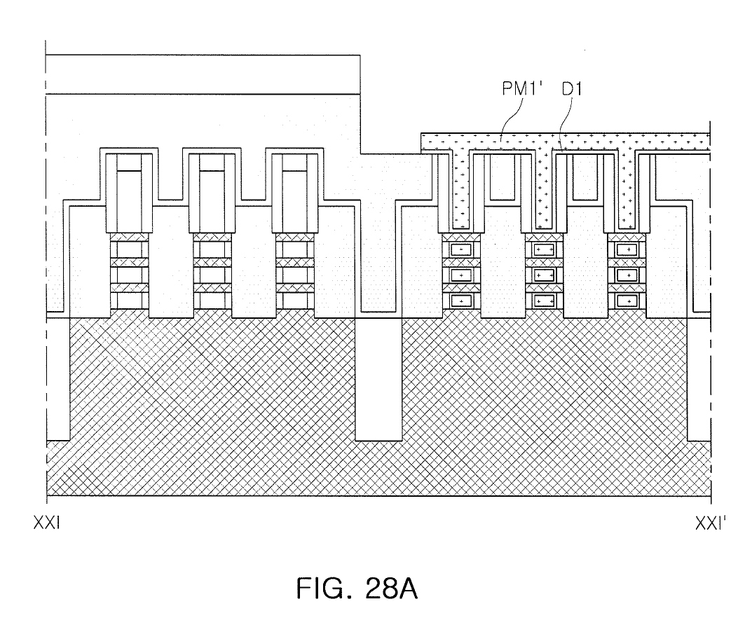

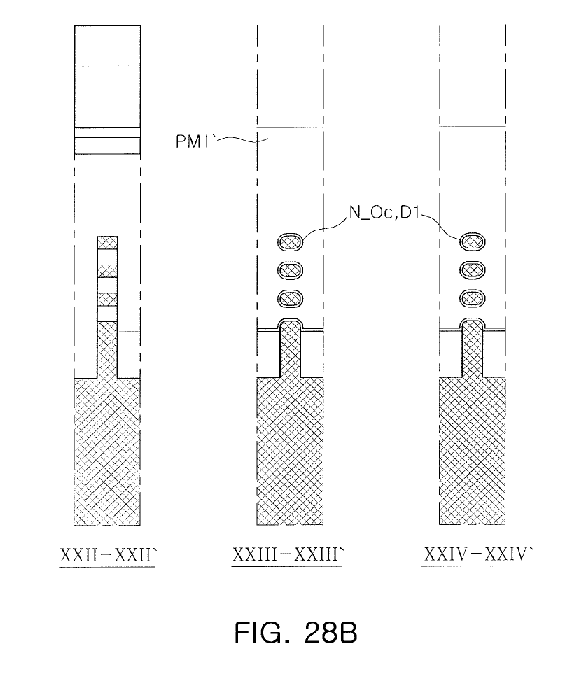

With reference to FIGS. 25, 28A, and 28B, a first protective mask PM1′ may be formed on the first device region P_DA through patterning the protective layer PM1. When the first protective mask PM1′ is formed, the first dielectric D1 on the first device region P_DA may be exposed. The exposed first dielectric D1 on the first device region P_DA and the common dielectric structure N_Oc below the first dielectric D1 may be etched to remove using the first protective mask PM1′ as an etching mask in S75. The first dielectric D1 and the common dielectric structure N_Oc may remain on the second device region N_DA.

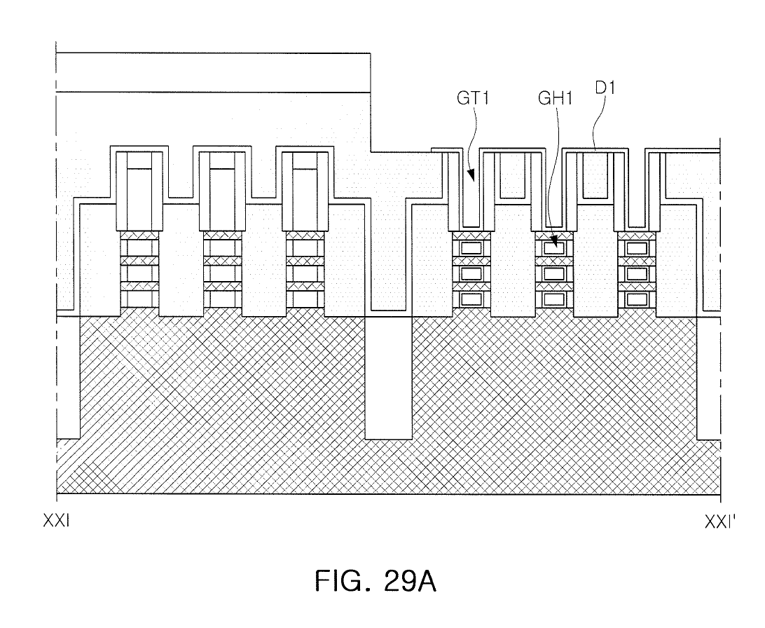

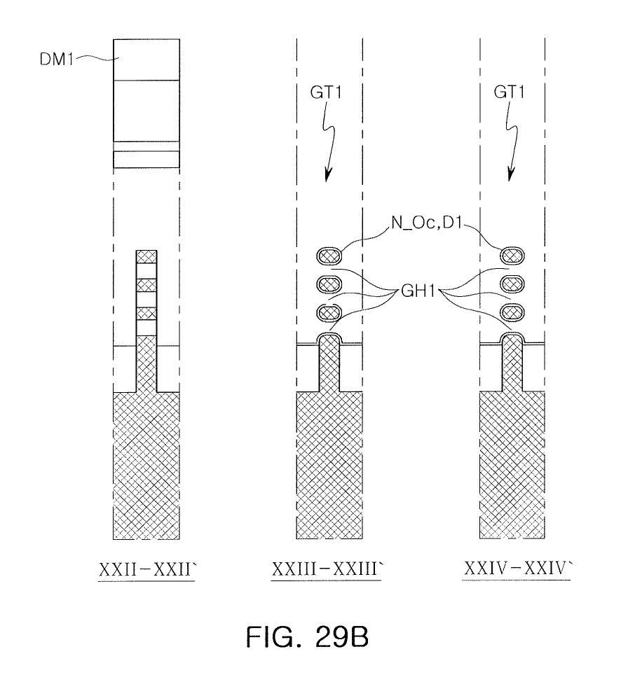

With reference to FIGS. 29A and 29B, the first protective mask PM1′ may be removed in S80. The first protective mask PM1′ may be removed using a wet etching process.

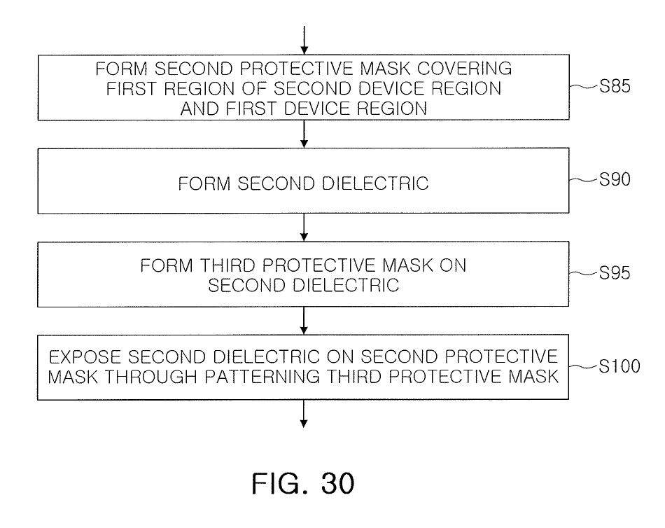

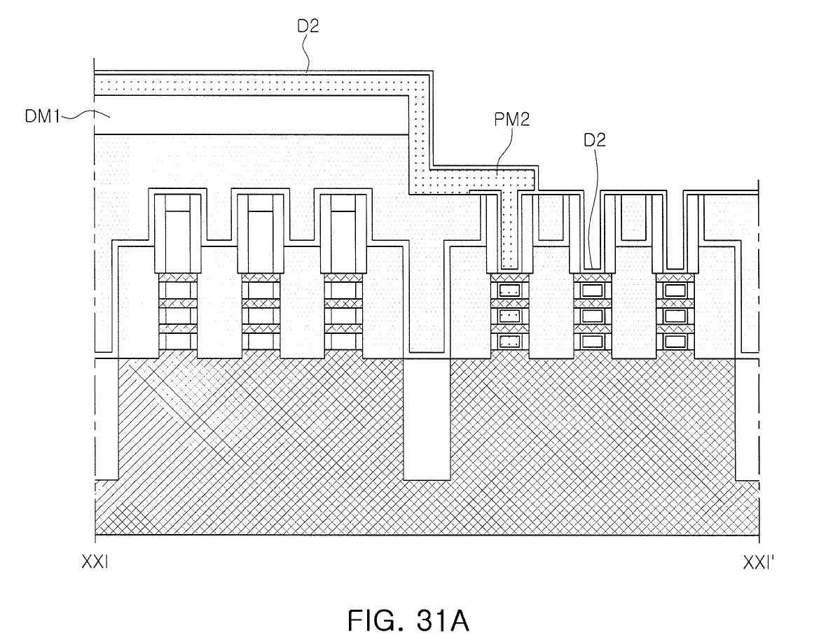

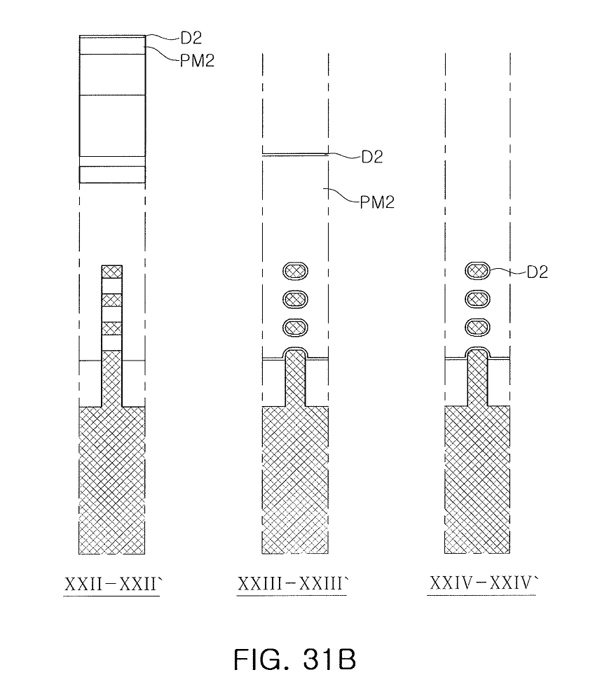

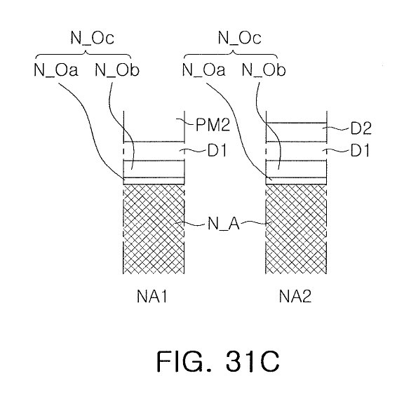

With reference to FIGS. 30, 31A, 31B, and 31C, a second protective mask PM2 covering a first region NA1 of the second device region N_DA and the first device region P_DA may be formed in S85. The second protective mask PM2 may include a material the same as that of the first protective mask (see PM1′ in FIGS. 28A and 28B). A second dielectric D2 may be formed in S90. The second dielectric D2 may be formed conformally on a substrate including the second protective mask PM2. The first dielectric D1 remaining in the first region NA1 in the second device region N_DA may be covered by the second protective mask PM2. In addition, the first dielectric D1 remaining in the second NA2 in the second device region N_DA may be covered by the second dielectric D2.

In an example embodiment, the second dielectric D2 may correspond to the second upper dielectric (see N_O2a in FIG. 8) of the second NMOS dielectric structure (see N_O2 in FIG. 8). For example, the second dielectric D2 formed on the first dielectric D1 may be referred to as the second upper dielectric (see N_O2a in FIG. 8). Furthermore, the first dielectric D1 below the second dielectric D2 may be referred to as the first upper dielectric (see N_O2a in FIG. 8).

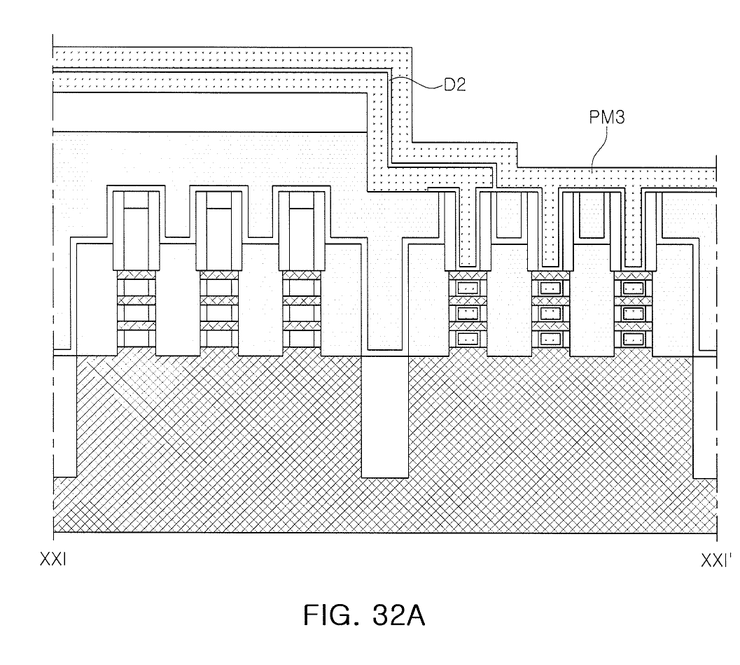

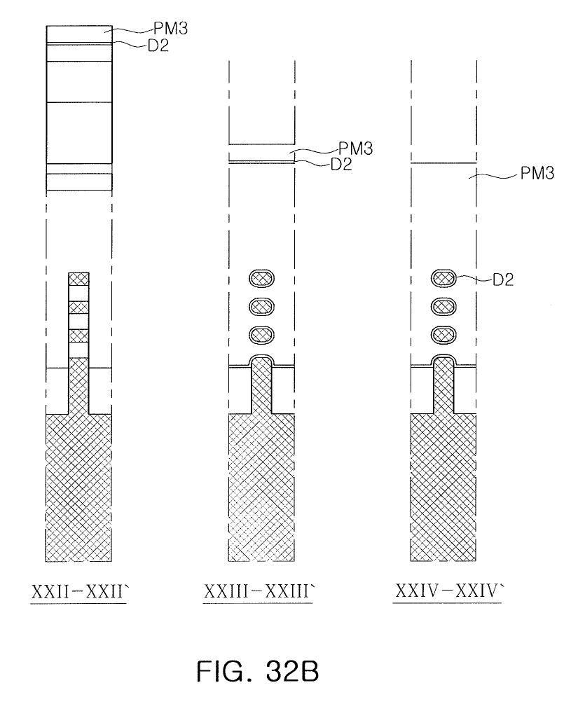

With reference to FIGS. 30, 32A, and 32B, a third protective mask PM3 may be formed on the second dielectric D2 in S95. The third protective mask PM3 may include a material the same as that of the second protective mask PM2.

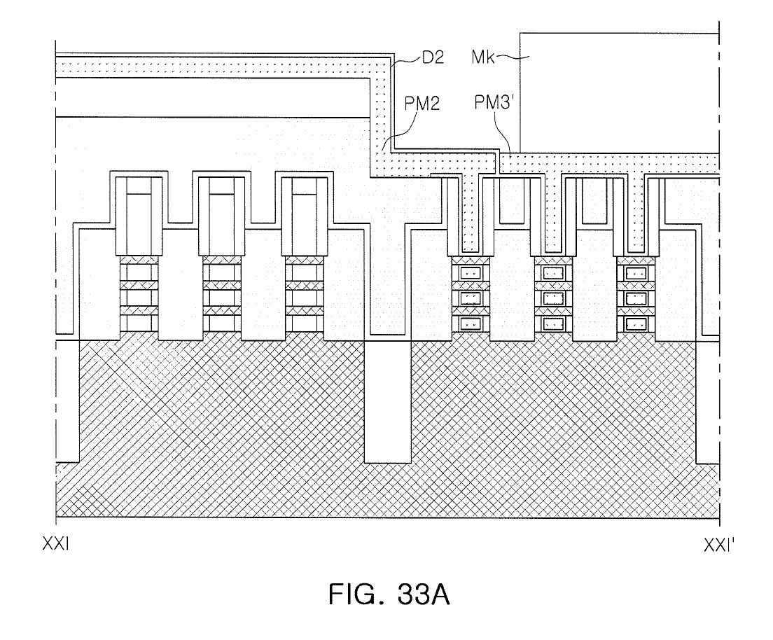

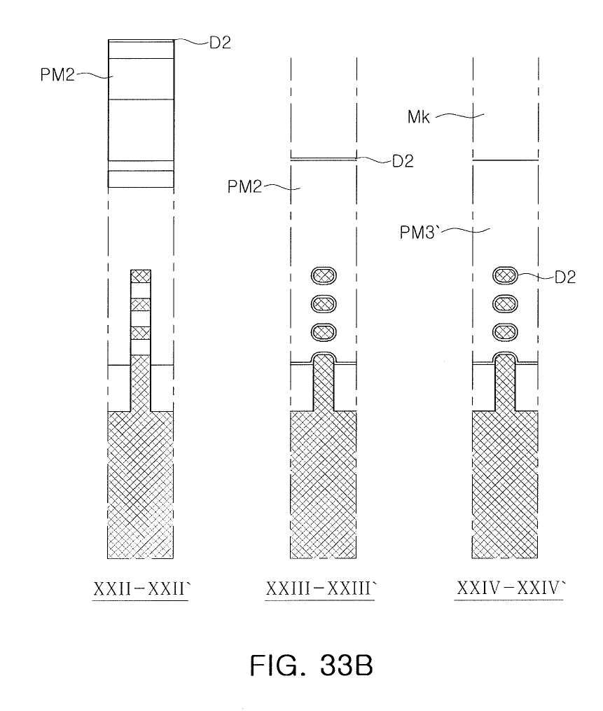

With reference to FIGS. 30, 33A, and 33B, a patterned third protective mask PM3′ may be formed through patterning the third protective mask PM3. Patterning the third protective mask PM3 may include forming a patterned mask MK on the third protective mask PM3 and etching the third protective mask PM3 using the patterned mask MK as an etching mask. The second dielectric D2 on the second protective mask PM2′ may be exposed through patterning the third protective mask PM3 in S100.

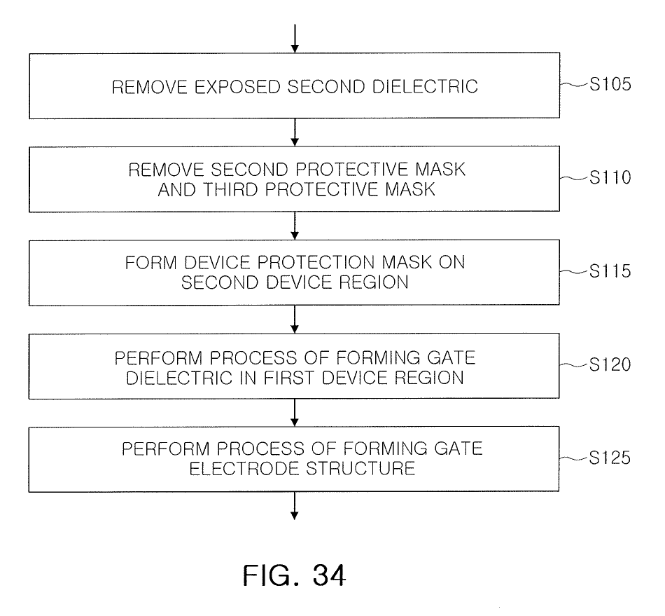

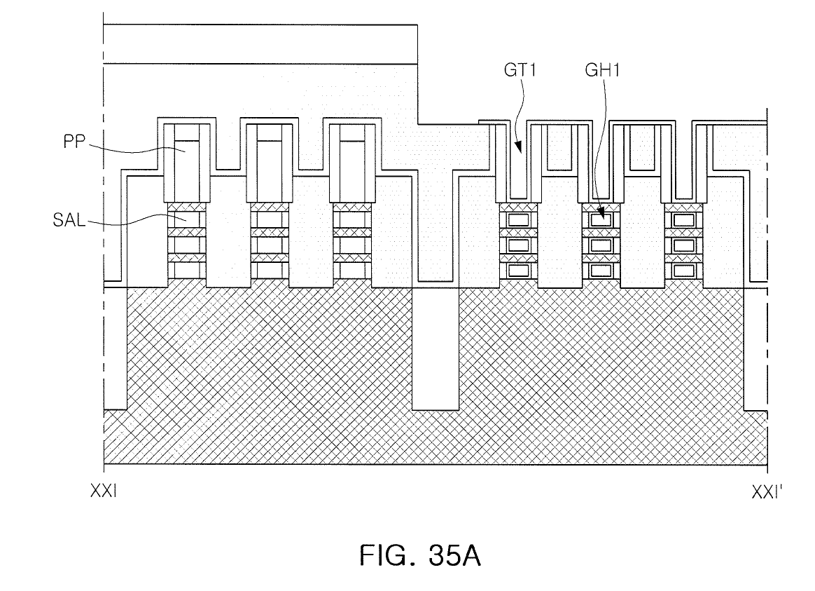

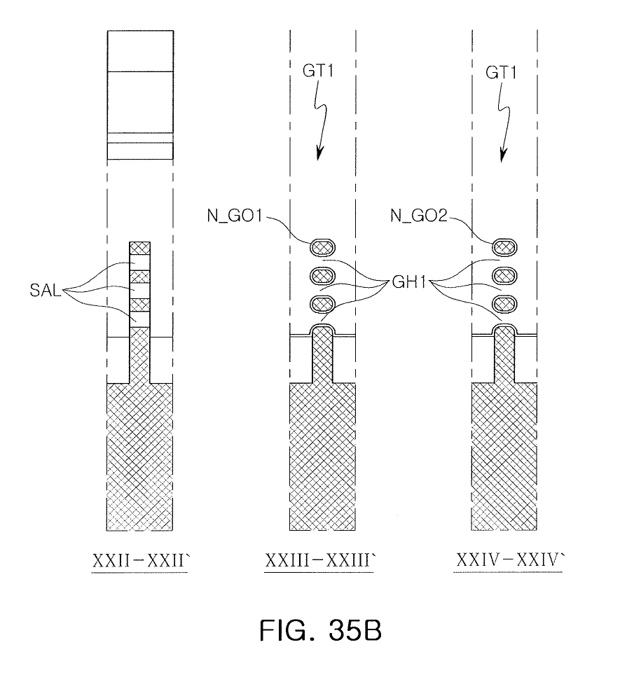

With reference to FIGS. 34, 35A, and 35B, the exposed second dielectric D2 disposed on the second protective mask PM2 may be removed in S105. Therefore, the second protective mask PM2 may be exposed. The third protective mask PM3′ may be exposed through removing the patterned mask MK. The exposed second protective mask PM2 and the exposed third protective mask PM3′ may be removed in S110. The exposed second protective mask PM2 and the exposed third protective mask PM3′ may be removed using a wet etching process. Therefore, a first NMOS gate dielectric structure N_GO1 as illustrated in FIG. 7 may be formed on the first region NA1 in the second device region N_DA. In addition, a second NMOS gate dielectric structure N_GO2, as illustrated in FIG. 8, may be formed on the second region NA2 in the second device region N_DA.

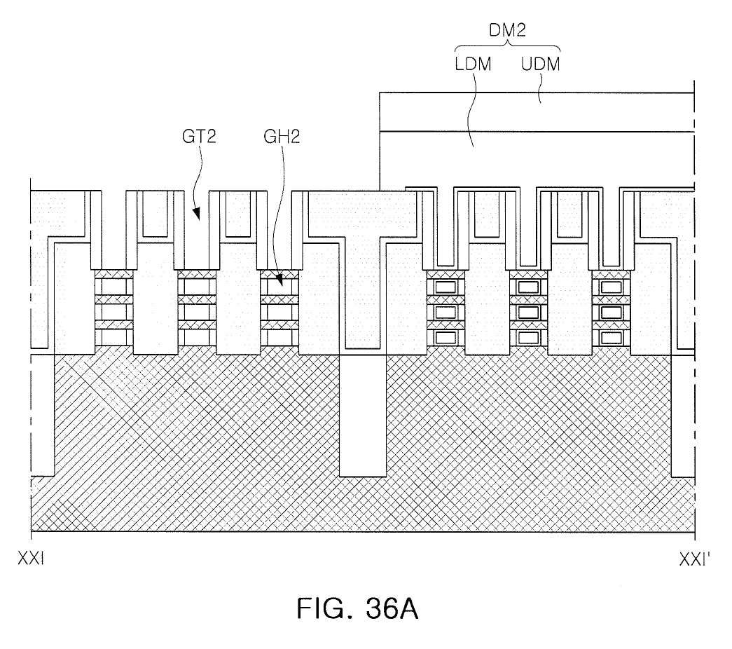

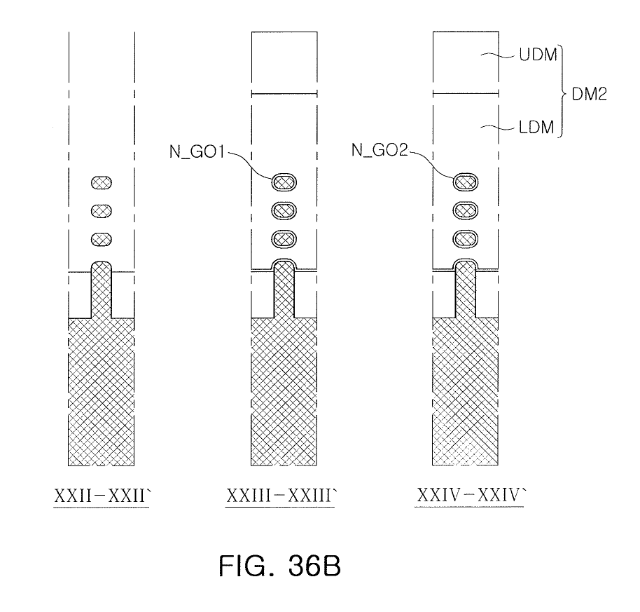

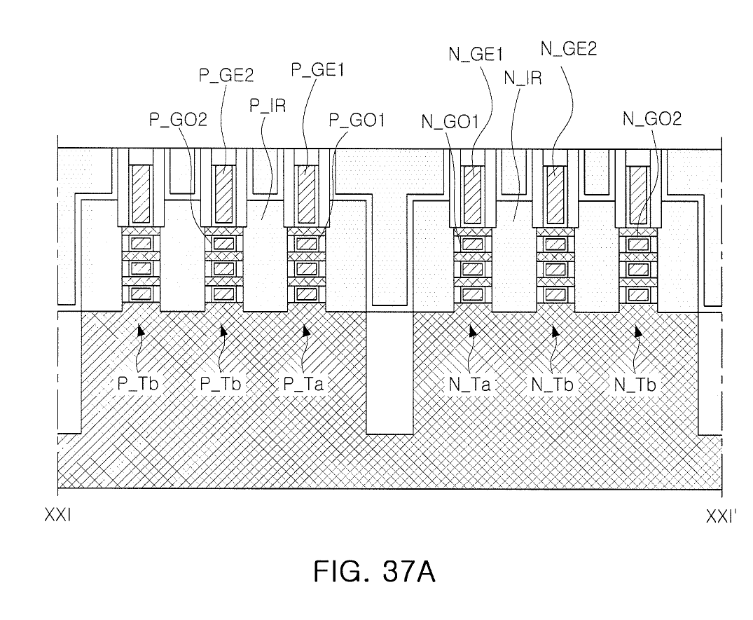

With reference to FIGS. 34, 36A, and 36B, a second device protection mask DM2 may be formed on the second device region N_DA in S115. Forming the second device protection mask DM2 may include forming a lower device protection mask LDM covering the second device region N_DA on a substrate in which the first NMOS gate dielectric structure N_GO1 and the second NMOS gate dielectric structure N_GO2 are exposed and forming an upper device protection mask UDM on the lower device protection mask LDM.

The lower device protection mask LDM may be in direct contact with the first NMOS gate dielectric structure N_GO1 and the second NMOS gate dielectric structure N_GO2, and may include a material having a high selective etching rate with the first NMOS gate dielectric structure N_GO1 and the second NMOS gate dielectric structure N_GO2. For example, the lower device protection mask LDM may be formed using a metallic nitride, such as a Ti nitride. The upper device protection mask UDM may include a material, such as a Si nitride.

In FIGS. 23A to 24B, gate trenches GT2 and holes GH2 may be formed in the first device region P_DA using the substantially same method as that of the second device region N_DA. For example, gate holes GH2 may be formed in such a manner that the mask line (see PP in FIG. 35A) on the first device region P_DA is exposed through an etching process using the second device protection mask DM2 as an etching mask, gate trenches GT2 are formed by selectively removing the mask line (see PP in FIG. 35A), and sacrificial patterns (see SAL in FIGS. 35A and 35B) exposed by the gate trenches GT2 are removed.

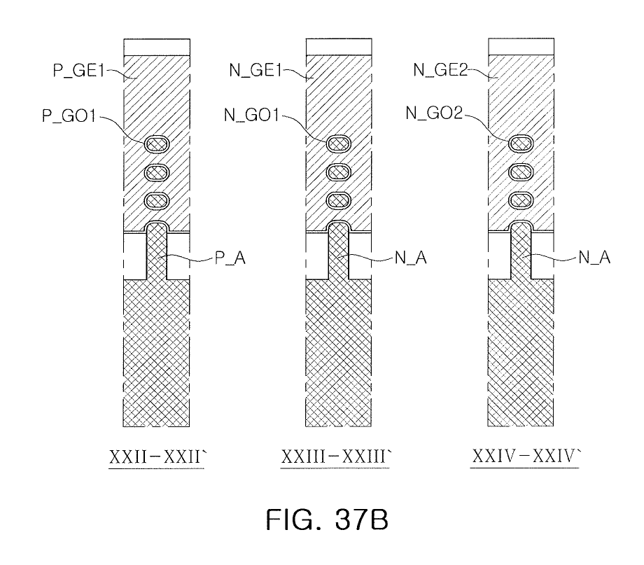

With reference to FIGS. 34, 37A, and 37B, a process of forming a gate dielectric in the first device region P_DA may be performed in S120. During the process of forming the gate dielectric in the first device region P_DA, the first NMOS gate dielectric structure N_GO1 and the second NMOS gate dielectric structure N_GO2 in the first device region P_DA may be protected by the second device protection mask DM2.

The process of forming the gate dielectric in the first device region P_DA may be performed in the substantially same process as that illustrated in FIGS. 25 to 35B, and only a type of a dielectric material is changed into a dielectric material formed in the first device region P_DA. Therefore, a first PMOS gate dielectric structure P_GO1 and the second PMOS gate dielectric structure P_GO2 may be formed in the first device region P_DA.

Subsequently, the second device protection mask DM2 may be removed, and the process of forming a gate electrode may be performed. Therefore, a semiconductor device illustrated in FIGS. 11, 12A, 12B, and 13 may be formed.

In the same manner as the method illustrated above, the method of forming a semiconductor device according to an example embodiment may provide a method of forming the first NMOS gate dielectric structure N_GO1 and the second NMOS gate dielectric structure N_GO2 having different structures in the second device region N_DA. Among the methods, dielectrics having other structures may be formed in the second device region N_DA in such a manner that a method following the process (S60) of forming the common dielectric structure illustrated in FIG. 25 is repeated. Therefore, gate dielectric structures having various structures may be formed using the method of forming a semiconductor device according to an example embodiment.

As set forth above, according to example embodiments, a semiconductor device including MOS transistors may be provided, which may significantly reduce an increase in a thickness of a gate and provide different threshold voltages. Gate dielectric structures of gates of the MOS transistors may be formed using a first shifter and a second shifter that may act as a shifter changing a threshold voltage. One of the first shifter and the second shifter may be provided as a dipole layer. In the gate dielectric structures formed using the shifters, the thicknesses of the gates of the MOS transistors having various threshold voltages may be reduced.

According to example embodiments, a semiconductor device including the MOS transistors having a gate all around (GAA) structure, adopting the gate dielectric structures may be provided. As a device size in the MOS transistors having the GAA structure has become gradually smaller, a distance between channel semiconductor layers surrounded by the gate has become gradually shorter. As such, since a structure of the gates that may reduce a thickness thereof may be disposed between the channel semiconductor layers having a distance shortened therebetween, process defects occurring during a process of forming the gates may be reduced. Thus, productivity of the semiconductor device may be improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor device, comprising:
a first metal oxide semiconductor (MOS) transistor including first source/drain regions on a semiconductor substrate, a first semiconductor layer between the first source/drain regions and spaced apart from the semiconductor substrate, a first gate electrode structure intersecting and surrounding the first semiconductor layer, and a first gate dielectric structure between the first semiconductor layer and the first gate electrode structure; and
a second MOS transistor including second source/drain regions on the semiconductor substrate, a second semiconductor layer between the second source/drain regions, spaced apart from the semiconductor substrate, and having the same conductivity as the conductivity of the first semiconductor layer, a second gate electrode structure intersecting and surrounding the second semiconductor layer, and a second gate dielectric structure between the second semiconductor layer and the second gate electrode structure,
wherein the first gate dielectric structure and the second gate dielectric structure include a first common dielectric structure,
the first gate dielectric structure includes a first upper dielectric on the first common dielectric structure,
the second gate dielectric structure includes the first upper dielectric and a second upper dielectric, and
one of the first upper dielectric and the second upper dielectric is provided as a material forming a dipole layer.

2. The device as claimed in claim 1, wherein the first upper dielectric of the first gate dielectric is between the first common dielectric structure of the first gate dielectric and the first gate electrode structure, and the first upper dielectric and the second upper dielectric of the second gate dielectric structure are between the first common dielectric structure of the second gate dielectric structure and the second gate electrode structure.

3. The device as claimed in claim 1, wherein the first common dielectric structure includes an interface dielectric and a common high-k dielectric, and the common high-k dielectric is a material different from the first upper dielectric and the second upper dielectric.

4. The device as claimed in claim 1, wherein the first MOS transistor is provided as a first PMOS transistor, and the second MOS transistor is provided as a second PMOS transistor.

5. The device as claimed in claim 4, further comprising:
a first NMOS transistor including first NMOS source/drain regions on the semiconductor substrate, a first NMOS semiconductor layer between the first NMOS source/drain regions, a first NMOS gate electrode structure surrounding the first NMOS semiconductor layer, and a first NMOS gate dielectric structure between the first NMOS semiconductor layer and the first NMOS gate electrode structure; and
a second MOS transistor including second NMOS source/drain regions on the semiconductor substrate, a second NMOS semiconductor layer between the second NMOS source/drain regions, a second NMOS gate electrode structure surrounding the second NMOS semiconductor layer, and a second gate dielectric structure between the second NMOS semiconductor layer and the second gate electrode structure,
wherein the first NMOS gate dielectric structure and the second NMOS gate dielectric structure include a second common dielectric structure, the first NMOS gate dielectric structure includes the second upper dielectric, and the second NMOS gate dielectric structure includes the first upper dielectric and the second upper dielectric.

6. The device as claimed in claim 5, wherein the second upper dielectric is provided as a material forming the dipole layer.

7. The device as claimed in claim 1, wherein the remainder of the first upper dielectric and the second upper dielectric is provided as an aluminum (Al)-based dielectric.

8. The device as claimed in claim 1, wherein the first gate electrode structure and the second gate electrode structure are adjacently to each other, one of the first source/drain regions and one of the second source/drain regions are provided as the same source/drain region, and the same source/drain region is between the first gate electrode structure and the second gate electrode structure.

9. A semiconductor device, comprising:
a first MOS transistor on a semiconductor substrate and including a first gate including a first gate dielectric structure and a first gate electrode structure;
a second MOS transistor on the semiconductor substrate and including a second gate dielectric structure and a second gate electrode structure;
a third MOS transistor on the semiconductor substrate and including a third gate including a third gate dielectric structure and a third gate electrode structure; and
a fourth MOS transistor on the semiconductor substrate and including a fourth gate including a fourth gate dielectric structure and a fourth gate electrode substrate,
wherein each of the first to fourth gate dielectric structures includes a common dielectric substrate, the first gate dielectric substrate includes a first upper dielectric on the common dielectric structure, the fourth gate dielectric structure includes a second upper dielectric on the common dielectric structure, and the second gate dielectric structure and the third gate dielectric structure include a mixture of the first upper dielectric and the second upper dielectric.

10. The device as claimed in claim 9, wherein the first MOS transistor includes a first vertical structure intersecting the first gate, the second MOS transistor includes a second vertical structure intersecting the second gate, the third MOS transistor includes a third vertical structure intersecting the third gate, and the fourth MOS transistor includes a fourth vertical structure intersecting the fourth gate, and each of the first to fourth vertical structures includes a plurality of semiconductor layers spaced apart from the semiconductor substrate and having the same conductivity.

11. The device as claimed in claim 9, wherein the common dielectric structure includes an interface dielectric and a common high-k dielectric on the interface dielectric, the interface dielectric includes a silicon (Si)-based dielectric, and the common high-k dielectric includes a hafnium (Hf)-based dielectric.

12. The device as claimed in claim 11, wherein the second upper dielectric is provided as a material forming a dipole layer.

13. The device as claimed in claim 12, wherein the second upper dielectric includes a lanthanum (La)-based dielectric or a magnesium (Mg)-based dielectric.

14. The device as claimed in claim 9, wherein the second MOS transistor and the third MOS transistor have different threshold voltages.

15. The device as claimed in claim 9, wherein a portion of the second upper dielectric in the second gate dielectric structure is different from the portion of the second upper dielectric in the third gate dielectric structure.

16. A semiconductor device, comprising:
a first transistor, the first transistor being of a first conductivity type, the first transistor including a semiconductor layer between source/drain regions, and a gate electrode structure surrounding the semiconductor layer and spaced apart therefrom by a first gate dielectric structure; and
a second transistor, the second transistor being of the first conductivity type and having a different threshold voltage from the first transistor, the second transistor including a semiconductor layer between source/drain regions, and a gate electrode structure surrounding the semiconductor layer and spaced apart therefrom by a second gate dielectric structure, wherein:
the first gate dielectric structure and the second gate dielectric structure each include a same high-k dielectric material,
the first gate dielectric structure includes a first dielectric material on the high-k dielectric material, and
the second gate dielectric structure includes a second dielectric material on the high-k dielectric material, the second dielectric material forming a dipole.

17. The device as claimed in claim 16, wherein the high-k dielectric material includes hafnium, the first dielectric material includes aluminum, and the second dielectric material includes one or more of lanthanum or magnesium.

18. The device as claimed in claim 16, further comprising:
a third transistor, the third transistor being of a second conductivity type, the third transistor including a semiconductor layer between source/drain regions, and a gate electrode structure surrounding the semiconductor layer and spaced apart therefrom by a third gate dielectric structure; and
a fourth transistor, the fourth transistor being of the second conductivity type and having a different threshold voltage from the third transistor, the fourth transistor including a semiconductor layer between source/drain regions, and a gate electrode structure surrounding the semiconductor layer and spaced apart therefrom by a fourth gate dielectric structure, wherein:
the third gate dielectric structure and the fourth gate dielectric structure each include the same high-k dielectric material as the first and second transistors,
the third gate dielectric structure includes the first dielectric material on the high-k dielectric material, and
the fourth gate dielectric structure includes the second dielectric material on the high-k dielectric material.

19. The device as claimed in claim 18, further comprising:
a fifth transistor, the fifth transistor being of the first conductivity type and having a different threshold voltage from the first and second transistors, the fifth transistor including a semiconductor layer between source/drain regions, and a gate electrode structure surrounding the semiconductor layer and spaced apart therefrom by a fifth gate dielectric structure; and
a sixth transistor, the sixth transistor being of the first conductivity type and having a different threshold voltage from the first, second, and fifth transistors, the sixth transistor including a semiconductor layer between source/drain regions, and a gate electrode structure surrounding the semiconductor layer and spaced apart therefrom by a sixth gate dielectric structure, wherein:
the fifth gate dielectric structure and the sixth gate dielectric structure each include the same high-k dielectric material as the first and second transistors,
the fifth gate dielectric structure includes the first and second dielectric materials on the high-k dielectric material, and
the sixth gate dielectric structure includes the first and second dielectric materials on the high-k dielectric material, wherein the first dielectric material in the sixth transistor has a thickness that is greater than that of the first dielectric material in the fifth transistor, and the second dielectric material in the sixth transistor has a thickness that is less than that of the second dielectric material in the fifth transistor.

20. The device as claimed in claim 19, wherein the first conductivity type is p-type and the second conductivity type is n-type.
